(19) United States
(12) Patent Application Publication
(10) Pub. No.: US 2016/0163622 A1
(43) Pub. Date: Jun. 9, 2016

(54) PACKAGING-BEFORE-ETCHING FLIP CHIP 3D SYSTEM-LEVEL METAL CIRCUIT BOARD STRUCTURE AND TECHNIQUE THEREOF

(71) Applicant: JIANGSU CHANGJIANG ELECTRONICS TECHNOLOGY CO., LTD., Jiangsu (CN)

(72) Inventors: Steve Xin Liang, Jiangsu (CN); Chih-Chung Lilang, Jiangsu (CN); Yu-Bin Lin, Jiangsu (CN); Yaqin Wang, Jiangsu (CN); Youhai Zhang, Jiangsu (CN)

(21) Appl. No.: 14/901,547

(22) PCT Filed: Dec. 3, 2013
(86) PCT No.: PCT/CN2013/088376

§ 371 Date: Dec. 28, 2015

(30) Foreign Application Priority Data
Aug. 6, 2013 (CN) 201310340387.0

(51) Int. Cl. H01L 23/495; H01L 21/48; H01L 21/027; H01L 25/16; H01L 21/3105; H01L 23/31; H01L 23/60; H01L 25/065; H01L 21/288; H01L 21/56

(52) U.S. Cl. CPC H01L 23/49541; H01L 21/288; H01L 21/4825; H01L 21/0273; H01L 23/49582; H01L 21/565; H01L 21/563; H01L 21/31053; H01L 21/4828; H01L 23/49503; H01L 23/3114; H01L 23/60; H01L 25/0652; H01L 23/49575; H01L 23/4952; H01L 25/16; H01L 2225/0651

(57) ABSTRACT

Provided are a packaging-before-etching flip chip 3D system-level metal circuit board structure and technique thereof. The metal circuit board structure comprises a metal substrate frame; the front face of the metal substrate frame is provided with pins; the front faces of the pins are provided with conductive posts; chips are installed in a flip manner between the pins via underfills; the peripheral areas of the pins, the conductive posts and the chip are encapsulated with molding compound, the top of the molding compound being parallel to the tops of the conductive posts; and the surfaces of the metal substrate frame, the pins and the conductive posts exposing out of the molding compounds are provided with an anti-oxidation layer, thus solving the problem of limited functionality and application of a traditional metal lead frame due to the fact that objects cannot be embedded therein.

This application claims the priority to Chinese Patent Application No. 201310340387.0, titled “PACKAGING-BEFORE-ETCHING FLIP CHIP 3D SYSTEM-IN-PACKAGE METAL CIRCUIT BOARD STRUCTURE AND TECHNIQUE THEREOF” and filed with the Chinese State Intellectual Property Office on Aug. 6, 2013, which is incorporated herein by reference in its entirety.

### FIELD

The present disclosure relates a packaging-before-etching flip chip 3D system-in-package metal circuit board structure and a process method thereof, belonging to the field of semiconductor packaging technology.

### BACKGROUND

Basic processing methods for manufacturing a conventional metal lead frame are as follows.

1. A metal sheet is provided to be punched from up to down or from down to up in a longitudinal manner by a punching technology using a mechanical upper and lower tool (see FIG. 87), such that a lead frame with a die pad for supporting a chip, an inner lead for transmitting a signal and an outer lead for connecting to an external PCB (printed circuit board) can be formed in the metal sheet, thereafter certain regions of the inner lead and/or the die pad are coated with a metal plating layer to form a lead frame which can be actually used (see FIG. 88, FIG. 89).

2. A metal sheet is provided to be exposed and developed to form a window and to be chemically etched by the technology of chemical etching (see FIG. 90), such that a lead frame with a die pad for supporting a chip, an inner lead for transmitting a signal and an external lead for connecting to an external PCB can be formed in the metal sheet, thereafter certain regions of the inner lead and/or the die pad are coated with a metal plating layer to form a lead frame that can be actually used (see FIG. 91).

3. Another method is as follows. Attaching a layer of high temperature resistant adhesive film which can resist 260 [symbol] is on a back surface of the lead frame, after a lead frame with a die pad for supporting a chip, an inner lead for transmitting signal and an external lead for connecting to an external PCB has been formed and certain regions of the inner lead and/or the die pad have been coated with a metal plating layer based on a first method and a second method, such that the lead frame becomes a lead frame which can be used in a QFN (Quad Flat No Lead) package and a molding volume shrunk package (see FIG. 92).

4. Yet another method is as follows. Pre-molding is performed on a lead frame, after the lead frame with a die pad for supporting a chip, an inner lead for transmitting signal and an outer lead for connecting to an external PCB has been formed and certain regions of the inner lead and/or the die pad have been coated with a metal plating layer utilizing the first method or the second method, a thermosetting epoxy resin is filled in a region where the metal sheet has been punched or been chemically etched, such that the lead frame becomes a pre-molded lead frame which can be used in a QFN package, a molding volume shrunk package and a copper wire bonding package (see FIG. 93).

The conventional process method described above has the following disadvantages.

1. for the lead frame realized by the mechanical punching,

A) due to performing a punching from up to down or from down to up using an up-down tool to form a vertical cross section, the mechanical punching will result in being unable to perform other functions or embed other objects inside the lead frame, for example, objects of the system are integrated in the metal lead frame itself;

B) mechanical stamping refers to extruding edges of the metal sheet using the up-down tool, to extend out a metal region, and the length of the extended metal region due to extruding is at most 80 percents of the thickness of the lead frame (see FIG. 94). In the case where the length of the extended metal region is greater than 80 percents of the thickness of the lead frame, the extended metal region due to extruding may easily experience warp, crack, break, irregular shape, surface pores and the like, which occur to an ultra-thin lead frame more easily (see FIG. 95);

C) in the case where the length of the extended metal region due to the mechanical stamping is less than or just equal to 80 percents of the thickness of the lead frame, related objects cannot be placed in the extended metal region due to an insufficient extension length, especially for an ultra-thin lead frame (see FIG. 96).

2. For the lead frame realized by the chemical etching technology,

A) subtraction etching is to adopt half etching technology to etch space of objects required to be embedded, and the biggest disadvantages thereof is that a depth of the etching and the flatness of a plane formed after the etching are uncontrollable(see FIG. 97);

B) after the space of objects required to be embedded are formed in the metal plate by the half etching, the lead frame may has a weak structure strength, which will directly affect difficulty of a working condition (for example, pick-and-place, transport, high temperature, high pressure and thermal stress shrinkage) required when an object is embedded subsequently;

C) the lead frame realized by the chemical etching technology represents at most an outer lead pattern and an inner lead pattern at a front surface and a back face of the lead frame, and it is completely unable to represent the multi-layer 3D circuit system-in-package metal lead frame.

### SUMMARY

A packaging-before-etching flip chip 3D system-in-package metal circuit board structure and a processing method thereof are provided to overcome the above disadvantages, which can solve the problem of objects incapable of being embedded in the conventional metal wiring frame to limit the function and application performance of the metal wiring frame:

The objects of the disclosure can be achieved by a processing method for manufacturing packaging-before-etching flip chip 3D system-in-package metal circuit board structure, wherein, the processing method comprises:

step 1: providing a metal substrate;

step 2: pre-plating a surface of the metal substrate with a copper material,

wherein the surface of the metal substrate is pre-plated with a layer of copper material;

step 3: attaching a photoresist film,

wherein a front surface and a back surface of the metal substrate which have been pre-plated with the copper material in step 2 are respectively attached with the photoresist film which can be exposed and developed;

step 4: removing a part of the photoresist film on the front surface of the metal substrate,

wherein the front surface of the metal substrate which has been attached with the photoresist film in step 3 is exposed and developed with a pattern using an exposure and development equipment, and the part of the photoresist film in the pattern is removed, so as to expose a region of the front surface of the metal substrate to be plated with a metal wiring layer later;

step 5: plating with the metal wiring layer,

wherein the region of the front surface of the metal substrate from which the part of the photoresist film has been removed in step 4 is plated with the metal wiring layer, so that a die pad and a lead are formed on the front surface of the metal substrate;

step 6: attaching a photoresist film,

wherein the front surface of the metal substrate which has been plated with the metal wiring layer in step 5 is attached with the photoresist film which can be exposed and developed;

step 7: removing a part of the photoresist film on the front surface of the metal substrate,

wherein the front surface of the metal substrate which has been attached with the photoresist film in step 6 is exposed and developed with a pattern using an exposure and development equipment, and the part of the photoresist film in a pattern is removed, so as to expose a region of the front surface of the metal substrate to be plated with a conductive pillar later;

step 8: plating with the conductive pillar,

wherein the region of the front surface of the metal substrate from which the part of the photoresist film has been removed in step 7 is plated with the conductive pillar;

step 9: removing the photoresist film,

wherein the photoresist film on the surface of the metal substrate is removed;

step 10: bonding die,

wherein a chip is flipped on a front surface of the die pad formed in step 5 by underfills;

step 11: molding with an epoxy resin,

wherein the molding with the epoxy resin for protecting is performed on the front surface of the metal substrate after the bonding die has been performed;

step 12: grinding a surface of the epoxy resin,

wherein the surface of the epoxy resin is ground after molding with the epoxy resin has been performed in step 11;

step 13: attaching a photoresist film,

wherein the front surface and the back surface of the metal substrate are attached with the photoresist film which can be exposed and developed after the surface of the epoxy resin has been ground in step 12;

step 14: removing a part of the photoresist film on the back surface of the metal substrate,

wherein the back surface of the metal substrate, which has been attached with the photoresist film in step 13, is exposed and developed with a pattern using an exposure and development equipment, and the part of the photoresist film in the pattern is removed, so as to expose a region of the back surface of the metal substrate to be etched later;

step 15: etching,

wherein chemical etching is performed in the region of the back surface of the metal substrate from which the part of the photoresist film has been removed in step 14;

step 16: removing the photoresist film,

wherein the photoresist film on the surface of the metal substrate is removed, the photoresist film is removed by softening with chemicals and cleaning with high pressure water; and

step 17: plating with an anti-oxidizing metal layer or coating with an organic solderability preservative (OSP),

wherein an exposed metal surface of the metal substrate surface from which the photoresist film has been removed in step 16 is plated with the anti-oxidizing metal layer or is coated with the organic solderability preservative (OSP).

A processing method for manufacturing a packaging-before-etching flip chip 3D system-in-package metal circuit board structure is provided, which includes:

step 1: providing a metal substrate;

step 2: pre-plating a surface of the metal substrate with a copper material,

wherein the surface of the metal substrate is pre-plated with a layer of copper material;

step 3: attaching a photoresist film,

wherein a front surface and a back surface of the metal substrate which have been pre-plated with the copper material in step 2 are respectively attached with the photoresist film which can be exposed and developed;

step 4: removing a part of the photoresist film on the front surface of the metal substrate,

wherein the front surface of the metal substrate, which has been attached with the photoresist film in step 3 is exposed and developed with a pattern using an exposure and development equipment, and the part of the photoresist film in the pattern is removed, so as to expose a region of the front surface of the metal substrate to be plated with a metal wiring layer later;

step 5: plating with the metal wiring layer,

wherein the region of the front surface of the metal substrate from which the part of the photoresist film has been removed in step 4 is plated with the metal wiring layer, so that a die pad and a lead are formed on the front surface of the metal substrate;

step 6: attaching a photoresist film,

wherein the front surface of the metal substrate which has been plated with the metal wiring layer in step 5 is attached with the photoresist film which can be exposed and developed;

step 7: removing a part of the photoresist film on the front surface of the metal substrate,

wherein the front surface of the metal substrate which has been attached with the photoresist film in step 6 is exposed and developed with a pattern using an exposure and development equipment, and the part of the photoresist film in a pattern is removed, so as to expose a region of the front surface of the metal substrate to be plated with a conductive pillar later;

step 8: plating with the conductive pillar,

wherein the region of the front surface of the metal substrate from which the part of the photoresist film has been removed in step 7 is plated with the conductive pillar;

step 9: removing the photoresist film,

wherein the photoresist film on the surface of the metal substrate is removed;

step 10: bonding die,

wherein a chip is flipped on a front surface of the die pad formed in step 5 by underfills;

step 11: molding with an epoxy resin,

wherein the molding with the epoxy resin for protecting is performed on the front surface of the metal substrate after the bonding die has been performed;

step 12: grinding a surface of the epoxy resin,

wherein the surface of the epoxy resin is ground after the molding with the epoxy resin has been performed in step 11;

step 13: attaching a photoresist film,

wherein the front surface and the back surface of the metal substrate are attached with the photoresist film which can be exposed and developed after the surface of the epoxy resin has been ground in step 12;

step 14: removing a part of the photoresist film on the back surface of the metal substrate,

wherein the back surface of the metal substrate, which has been attached with the photoresist film in step 13, is exposed and developed with a pattern using an exposure and development equipment, and the part of the photoresist film in the pattern is removed, so as to expose a region of the back surface of the metal substrate to be etched later;

step 15: etching,

wherein chemical etching is performed in the region of the back surface of the metal substrate from which the part of the photoresist film has been removed in step 14;

step 16: removing the photoresist film,

wherein the photoresist film on the surface of the metal substrate is removed;

step 17: coating the back surface of the metal substrate with green paint,

wherein the back surface of the metal substrate is coated with the green paint or the photosensitive non-conductive adhesive material after the photoresist film has been removed in step 16;

step 18: exposing and developing to form a window,

wherein the green paint or the photosensitive non-conductive adhesive material with which the back surface of the metal substrate is coated is exposed an developed using an exposure and development equipment to form the window, so as to expose a region of the back surface of the metal substrate to be plated with a high conductivity metal layer later;

step 19: plating with the high conductivity metal layer,

wherein a region of the window formed in the green paint or the photosensitive non-conductive adhesive material on the back surface of the metal substrate in step 18 is plated with the high conductivity metal layer; and

step 20: plating with an anti-oxidizing metal layer or coating with an organic solderability preservative (OSP),

wherein an exposed metal surface of the metal substrate is plated with the anti-oxidizing metal layer or be coated with the organic solderability preservative (OSP).

A processing method for manufacturing a packaging-before-etching flip chip 3D system-in-package metal circuit board structure is provided, which includes:

step 1: providing a metal substrate;

step 2: pre-plating the surface of the metal substrate with a copper material,

wherein the surface of the metal substrate is pre-plated with a layer of copper material;

step 3: attaching a photoresist film,

wherein a front surface and a back surface of the metal substrate which have been pre-plated with the copper material in step 2 are attached with the photoresist film which can be exposed and developed;

step 4: removing a part of the photoresist film on the front surface of the metal substrate,

wherein the front surface of the metal substrate which has been attached with the photoresist film in step 3 is exposed and developed with a pattern using an exposure and development equipment, and the part of the photoresist film in the pattern is removed, so as to expose a region of the front surface of the metal substrate to be plated with a first metal wiring layer later;

step 5: plating with a first metal wiring layer,

wherein the region of the front surface of the metal substrate from which the part of the photoresist film has been removed in step 4 is plated with the first metal wiring layer;

step 6: attaching a photoresist film,

wherein the front surface of the metal substrate which has been plated with the first metal wiring layer in step 5 is attached with the photoresist film which can be exposed and developed;

step 7: removing a part of the photoresist film on the front surface of the metal substrate,

wherein the front surface of the metal substrate which has been attached with the photoresist film in step 6 is exposed and developed with a pattern using an exposure and development equipment, and the part of the photoresist film in the pattern is removed, so as to expose a region of the front surface of the metal substrate to be plated with a second metal wiring layer later;

step 8: plating with the second metal wiring layer,

wherein the region of the front surface of the metal substrate from which the part of the photoresist film has been removed in step 7 is plated with the second metal wiring layer, which servers as a conductive pillar to connect the first metal wiring layer to a third metal wiring layer;

step 9: removing the photoresist film,

wherein the photoresist film on the surface of the metal substrate is removed; step 10: attaching a non-conductive adhesive film,

wherein the front surface of the metal substrate is attached with a layer of non-conductive adhesive film;

step 11: grinding a surface of the non-conductive adhesive film,

wherein the surface of the non-conductive adhesive film is ground after the attaching the non-conductive adhesive film has been performed in step 10;

step 12: performing metallization pretreatment on the surface of the non-conductive adhesive film,

wherein the metallization pre-treatment is performed on the surface of the non-conductive adhesive film, so that a layer of metalized polymer material is adhered onto the surface of the non-conductive adhesive film, or roughening treatment is performed on the surface of the non-conductive adhesive film;

step 13: attaching a photoresist film,

wherein the front surface and the back surface of the metal substrate which have been metallized in step 12 are attached with the photoresist film which can be exposed and developed;

step 14: removing a part of the photoresist film on the front surface of the metal substrate,

wherein the front surface of the metal substrate, which has been attached with the photoresist film in step 13 is exposed and developed with a pattern using an exposure and development equipment, and the part of the photoresist film in the pattern is removed, so as to expose a region of the front surface of the metal substrate to be etched later;

step 15: etching,

wherein etching is performed in a region of the front surface of the metal substrate from which the part of the photoresis film has been removed in step 14;

step 16: removing the photoresist film,

wherein the photoresist film on the front surface of the metal substrate is removed;

step 17: plating with a third metal wiring layer,

wherein a remaining metallization pre-treatment region of the front surface of the metal substrate on which the etching has been performed in step 15 is plated with the third wiring layer, so that a die pad and a lead are formed on the front surface of the metal substrate;

step 18: attaching a photoresist film,

wherein the front surface of the metal substrate which has been plated with the third metal wiring layer in step 17 is attached with the photoresist film which can be exposed and developed;

step 19: removing a part of the photoresist film on the front surface of the metal substrate,

wherein the front surface of the metal substrate, which has been attached with the photoresist film in step 18, is exposed and developed with a pattern using an exposure and development equipment, and the part of the photoresist film in the pattern is removed, so as to expose a region of the front surface of the metal substrate to be plated with a conductive pillar later;

step 20: plating with the conductive pillar,

wherein the region of the front surface of the metal substrate from which the part of the photoresist film has been removed in step 19 is plated with the conductive pillar;

step 21: removing the photoresist film,

wherein the photoresist film on the surface of the metal substrate is removed;

step 22: bonding die,

wherein a chip is flipped on a front surface of the die pad formed in step 17 by underfills;

step 23: molding with epoxy resin,

wherein the molding with the epoxy resin for protecting is performed on the front surface of the metal substrate after the bonding die has been performed;

step 24: grinding a surface of the epoxy resin,

wherein the surface of the epoxy resin is ground after the molding with the epoxy resin has been performed in step 23;

step 25: attaching a photoresist film,

wherein the front surface and the back surface of the metal substrate are attached with the photoresist film which can be exposed and developed after the surface of the epoxy resin has been ground in step 24;

step 26: removing a part of the photoresist film on the back surface of the metal substrate,

wherein the back surface of the metal substrate which has been attached with the photoresist film in step 25 is exposed and developed with a pattern using an exposure and development equipment, and the part of the photoresist film in the pattern is removed, so as to expose a region of the back surface of the metal substrate to be etched later;

step 27: etching,

wherein chemical etching is performed in the region of the back surface of the metal substrate from which the part of the photoresist film has been removed in step 26;

step 28: removing the photoresist film,

wherein the photoresist film on the surface of the metal substrate is removed; and

step 29: plating with an anti-oxidizing metal layer or coating with an organic solderability preservative (OSP),

wherein an exposed metal surface of the metal substrate surface from which the photoresist film has been removed in step 28 is plated with the anti-oxidizing metal layer or is coated with the organic solderability preservative (OSP).

Step 6 to step 17 may be repeated for times between step 8 and step 18.

A packaging-before-etching flip chip 3D system-in-package metal circuit board structure is provided, which includes: a metal substrate frame; a die pad and a lead provided in the metal substrate frame; a conductive pillar provided on a front surface of the lead; a chip is flipped on a front surface of the die pad and the lead by underfills; a molding material or epoxy resin with which a periphery region of the die pad, the lead, the conductive pillar and the chip is encapsulated, with the molding material or epoxy resin being flushed with the top of the conductive pillar; and an anti-oxidizing layer provided on a surface of the metal substrate frame, the die pad, the lead and the conductive pillar exposed from the molding material.

A plurality of turns of leads may be provided.

A passive device may be connected across the leads.

An electrostatic discharge coil may be provided between the die pad and the lead.

A plurality of the chips are flipped on a front surface of the die pads and the leads.

A second conductive pillar is provided on a front surface of the lead, and a second chip is flipped on the second conductive pillar via a conductive material, wherein, the second chip is located above the chip, and the second conductive pillar and the second chip are located inside the molding material.

A second chip may be replaced with a passive device.

A packaging-before-etching flip chip 3D system-in-package metal circuit board structure is provided, which includes: a metal substrate frame; a lead provided in a front surface of the metal substrate frame, a conductive pillar provided on a front surface of the lead; a chip is flipped between the leads by underfills; a molding material with which a periphery region of the lead, the conductive pillar and the chip is encapsulated, with the molding material being flushed with the top of the conductive pillar; and an anti-oxidizing layer provided on a surface of the metal substrate frame, the lead and the conductive pillar exposed from the molding material.

A packaging-before-etching flip chip 3D system-in-package metal circuit board structure is provided, which includes: a metal substrate frame; a die pad and a lead provided in the metal substrate frame; a conductive pillar provided on a front surface of the lead; a chip is flipped on a front surface of the die pad and the lead by underfills; a molding material with which a periphery region of the die pad, the lead, the conductive pillar and the chip is encapsulated, with the molding material being flushed with the top of the conductive pillar; a high conductivity metal layer provided on a back surface of the die pad and the lead; green paint filling between the high conductivity metal layers; and an anti-oxidizing layer provided on a surface of the metal substrate frame, the conductive pillar and the high conductivity metal layer exposed from the molding material and the green paint.

The 3D system-in-package metal circuit board structure can serves as a converter after being cut.

As compared with the conventional art, the present disclosure has beneficial effects as follows.

1. At present, each metal lead frame is manufactured by mechanical punching or chemical etching, multiple metal wiring layers can not be manufactured. And no object can be embedded into an interlayer inside the punching type metal lead frame. However, a three dimension metal wiring composite-type substrate provided in the present disclosure allows an object to be embedded into an interlayer inside the substrate.

2. A heat conductor or heat sink may be embedded into a required position or region in the interlayer inside the three dimension metal wiring composite-type substrate as required, so as to become a heat performance system-in-package metal lead frame (see FIG. 98).

3. An active element or assembly or a passive assembly may be embedded into a required position or region in the interlayer inside the three dimension metal wiring composite-type substrate as required by the system and function, so as to become a system-in-package metal lead frame.

4. It is totally unable to be found from the appearance of an finished product of the three dimension metal wiring composite-type substrate that an object has been embedded into an inner interlayer as required by system or function, especially an embedded silicon chip can not even be detected by X-ray, and thereby secrecy and protectiveness of the system and function can be sufficiently achieved.

5. A finished product of the three dimension metal wiring composite-type substrate includes various components in itself, if there is no need for a secondary packaging, the three dimension metal wiring composite-type substrate may be cut according to each cell, and each cell becomes an ultra thin package.

6. Except for having a function of implanting an object, the three dimension metal wiring composite-type substrate may be secondary packaged. And thereby an integration of system functions can be sufficiently achieved.

7. Except for having a function of implanting an object, the three dimension metal wiring composite-type substrate may be stacked with different unit package or system-in-package package at the outside of the package, and thereby dual system or multiple systems-on-chip packaging technology ability is sufficiently achieved.

8. The three dimension metal wiring substrate can be applied to multiple chip module (MCM) package (see FIG. 99 and FIG. 100). And the three dimension metal wiring substrate has lower cost and better flexibility than a conventional MCM substrate.

### BRIEF DESCRIPTION OF THE DRAWINGS

It is believed that the above features, advantages and objects of the present disclosure can be better understood by those skilled in the art through the following detailed description of embodiments of the present disclosure in conjunction with the drawings, in which:

FIG. 1 to FIG. 17 are respectively schematic procedure diagrams of a processing method for manufacturing a packaging-before-etching flip chip 3D system-in-package metal circuit board structure according to a first embodiment of the present disclosure;

FIG. 18 is a schematic diagram of a packaging-before-etching flip chip 3D system-in-package metal circuit board structure according to the first embodiment of the present disclosure;

FIG. 19 to FIG. 38 are respectively schematic procedure diagrams of a processing method for manufacturing a packaging-before-etching flip chip 3D system-in-package metal circuit board structure according to a second embodiment of the present disclosure;

FIG. 39 is a schematic diagram of a packaging-before-etching flip chip 3D system-in-package metal circuit board structure according to the second embodiment of the present disclosure;

FIG. 40 to FIG. 80 are respectively schematic procedure diagrams of a processing method for manufacturing a packaging-before-etching flip chip 3D system-in-package metal circuit board structure according to a third embodiment of the present disclosure;

FIG. 81 is a schematic diagram of a packaging-before-etching flip chip 3D system-in-package metal circuit board structure according to the third embodiment of the present disclosure;

FIG. 82 is a schematic diagram of a packaging-before-etching flip chip 3D system-in-package metal circuit board structure according to a fourth embodiment of the present disclosure;

FIG. 83 is a schematic diagram of a packaging-before-etching flip chip 3D system-in-package metal circuit board structure according to a fifth embodiment of the present disclosure;

FIG. 84 is a schematic diagram of a packaging-before-etching flip chip 3D system-in-package metal circuit board structure according to a sixth embodiment of the present disclosure;

FIG. 85 is a schematic diagram of a packaging-before-etching flip chip 3D system-in-package metal circuit board structure according to a seventh embodiment of the present disclosure;

FIG. 86 is a schematic diagram of a packaging-before-etching flip chip 3D system-in-package metal circuit board structure according to an eighth embodiment of the present disclosure;

FIG. 87 is a schematic structural diagram of a metal sheet which is subjected to mechanical punching up and down;

FIG. 88 is a schematic structural diagram of a punched strip type metal sheet;

FIG. 89 is a front schematic structural diagram of a lead frame formed by punching;

FIG. 90 is a schematic structural diagram of a metal sheet which is subjected to exposure and development to form a window by chemical etching;

FIG. 91 is a front schematic structural diagram of a lead frame which is formed by chemical etching;

FIG. 92 is a schematic structural diagram of a lead frame which may be used in a QFN package and a molding volume shrunk package;

FIG. 93 is a schematic structural diagram of a pre-molded molding material type lead frame which may be used in QFN package, a molding volume shrunk package and a copper wire bonding package;

FIG. 94 is a cross sectional view of a vertically extended metal region which is formed by extruding tools up and down;

FIG. 95 is a cross sectional view of crack, breakage and warp generated in the extended metal region which is formed by extruding tools up and down;

FIG. 96 is a cross sectional schematic structural diagram of a difficulty to embed an object in the case where the length of the extended metal region formed by extruding tools up and down is less than 80% of the thickness of the lead frame;

FIG. 97 is a cross sectional schematic structural diagram of non-uniform and flat unflatness of an etching depth;

FIG. 98 is a schematic structural diagram of a thermal performance system-in-package metal lead frame; and

FIG. 99 and FIG. 100 are schematic structural diagrams of a three dimension metal circuit substrate being applied to a multiple-chip module (MCM) package.

In the drawings:
metal substrate frame 1
die pad 2
lead 3
conductive pillar 4
chip 5
anti-oxidizing layer 6
molding material or epoxy resin 7
high conductivity metal layer 8
green paint or photosensitive non-conductive adhesive material 9
passive device 10
electrostatic discharge coil 11
second chip 12
second conductive pillar 13
conductive material 14
metal wire 15
underfill 16

### DETAILED DESCRIPTION

The technical solution according to the embodiments of the present disclosure will be described in detail in conjunction with the drawings in the embodiments of the present disclosure. It should be understood that the described embodiments are just a part of, rather than all of, the embodiments. Based on the embodiments of the present disclosure, all other embodiments obtained by those skilled in the art without creative work will fall within the protection scope of the present disclosure. The present disclosure provides a packaging-before-etching flip chip 3D system-in-package metal circuit board structure and a process method thereof.

First embodiment: a single wiring layer, a single flip chip and a single-turn lead (1).

Referring to FIG. 18, it is a packaging-before-etching flip chip 3D system-in-package metal circuit board structure provided in the present disclosure, and the structure includes: a metal substrate frame 1; a die pad 2 and a lead 3 provided on a front surface of the metal substrate frame 1; a conductive pillar 4 provided on a front surface of the lead 3; a chip 5 is flipped on a front surface of the die pad 2 and a lead 3 by underfills; a molding material or epoxy resin 7 with which a periphery region of the die pad 2, the lead 3, the conductive pillar 4 and the chip 5 is encapsulated, with the molding material or epoxy resin 7 being flushed with the top of the conductive pillar 4; and an anti-oxidizing layer 6 provided on the surface of the metal substrate frame 1, the die pad 2, the lead 3 and the conductive pillar 4 exposed from the molding material or epoxy resin 7.

A processing method for manufacturing a packaging-before-etching flip chip 3D system-in-package metal circuit board structure is described as follows.

Step 1: providing a metal substrate.

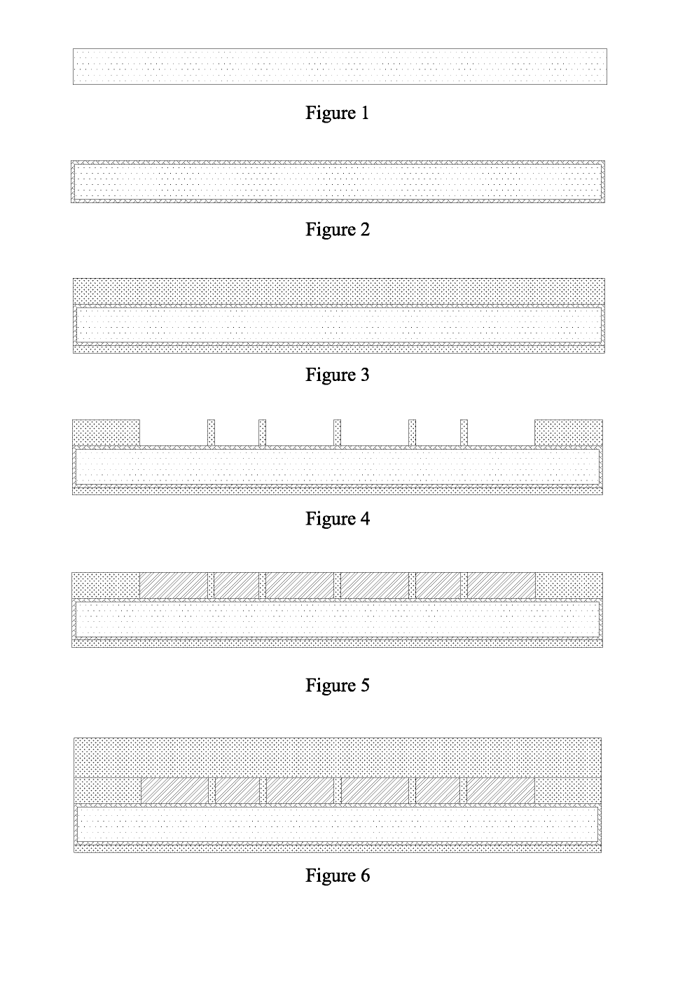

Referring to FIG. 1, the metal substrate having suitable thickness is provided. The metal substrate may be made from copper material, iron material, zinc plating material, stainless steel material, aluminum material or metallic or nonmetallic material which may achieve conductive function. The thickness of the metal substrate may be chosen depending on product properties.

Step 2: pre-plating the surface of the metal substrate with a copper material.

Referring to FIG. 2, the surface of the metal substrate is pre-plated with a layer of copper material. The copper layer has a thickness of 2 μm to 10 μm, which may also be thinned or thickened depending on a function requirement. The plating may be electrolytic plating, and chemical deposition may also be adopted.

Step 3: attaching a photoresist film.

Referring to FIG. 3, a front surface and a back surface of the metal substrate which have been pre-plated with the copper material in step 2 are respectively attached with the photoresist film which can be exposed and developed, in order to manufacture a metal wiring pattern later. The photoresist film may be a dry-type photoresist film or a wet-type photoresist film.

Step 4: removing a part of the photoresist film on the front surface of the metal substrate.

Referring to FIG. 4, the front surface of the metal substrate which has been attached with the photoresist film in step 3 is exposed and developed with a pattern using an exposure and development equipment, and the part of the photoresist film in the pattern is removed, so as to expose a region of the front surface of the metal substrate to be plated with a metal wiring layer later.

Step 5: plating with the metal wiring layer.

Referring to FIG. 5, the region of the front surface of the metal substrate from which the part of the photoresist film has been removed in step 4 is plated with the metal wiring layer, so that a die pad and a lead are formed on the front surface of the metal substrate. The metal wiring layer may be made from copper, aluminum, nickel, silver, gold, copper-silver, nickel-gold, nickel-palladium-gold or the like. The metal wiring layer has a thickness of 5 μm to 20 μm. The plated thickness may be varied depending on product properties. The plating may be electrolytic plating, and chemical deposition may also be adopted.

Step 6: attaching a photoresist film.

Referring to 6, the front surface of the metal substrate which has been plated with the metal wiring layer in step 5 is attached with the photoresist film which can be exposed and developed, in order to manufacture a conductive pillar later. The photoresist film may be a dry-type photoresist film or a wet-type photoresist film.

Step 7: removing a part of the photoresist film on the front surface of the metal substrate.

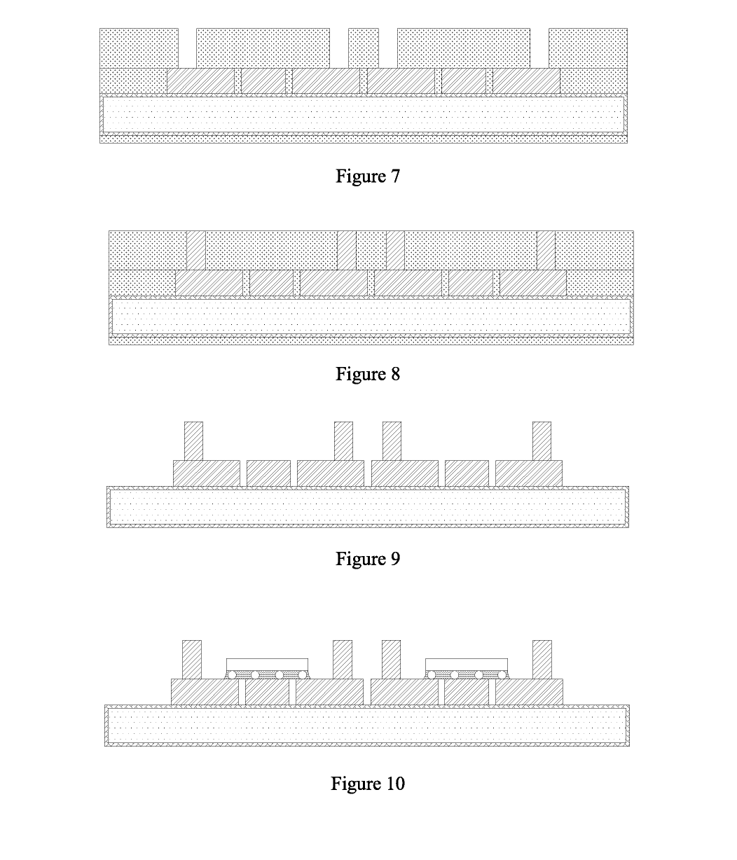

Referring to FIG. 7, the front surface of the metal substrate which has been attached with the photoresist film in step 6 is exposed and developed with a pattern using an exposure and development equipment, and the part of the photoresist film in a pattern is removed, so as to expose a region of the front surface of the metal substrate to be plated with a conductive pillar later.

Step 8: plating with the conductive pillar.

Referring to FIG. 8, the region of the front surface of the metal substrate from which a part of the photoresist film has been removed in step 7 is plated with the conductive pillar. The conductive pillar may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 9: removing the photoresist film.

Referring to FIG. 9, the photoresist film on the surface of the metal substrate is removed. The photoresist film may be removed by softening with chemicals and cleaning with high pressure water.

Step 10: bonding die.

Referring to FIG. 10, a chip is flipped on a front surface of the die pad and the lead formed in step 5 by underfills.

Step 11: molding with an epoxy resin.

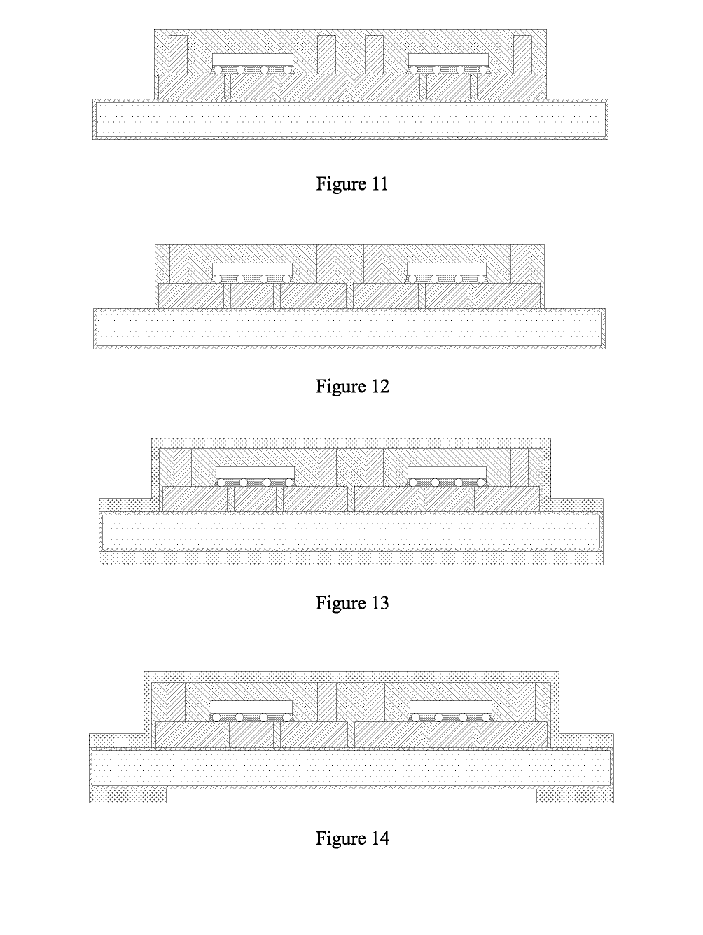

Referring to FIG. 11, the molding with the epoxy resin for protecting is performed on the front surface of the metal substrate after the bonding die has been performed. The epoxy resin material may be selected to be an epoxy resin with or without filler depending on product properties.

Step 12: grinding a surface of the epoxy resin.

Referring to FIG. 12, the surface of the epoxy resin is ground after the molding with the epoxy resin has been performed in step 11.

Step 13: attaching a photoresist film.

Referring to FIG. 13, the front surface and the back surface of the metal substrate are attached with the photoresist film adapted to expose and develop after the surface of the epoxy resin has been ground in step 12.

Step 14: removing a part of the photoresist film on the back surface of the metal substrate.

Referring to FIG. 14, the back surface of the metal substrate, which has been attached with the photoresist film in step 13, is exposed and developed with a pattern using an exposure and development equipment, and the part of the photoresist film in the pattern is removed, so as to expose a region of the back surface of the metal substrate to be etched later.

Step 15: etching.

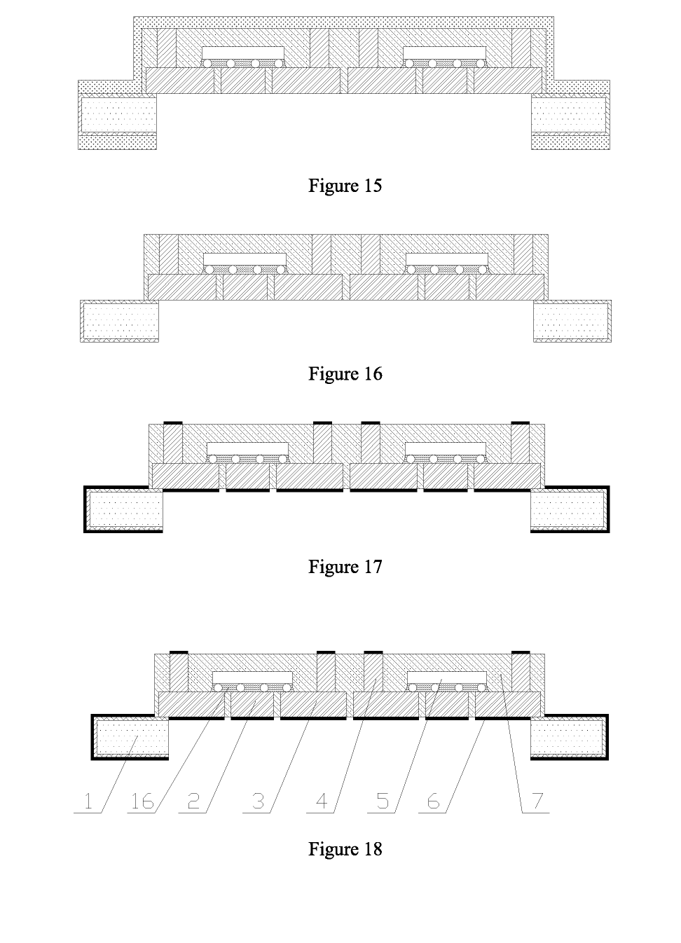

Referring to FIG. 15, chemical etching is performed in the region of the back surface of the metal substrate from which the part of the photoresist film has been removed in step 14.

Step 16: removing the photoresist film.

Referring to FIG. 16, the photoresist film on the surface of the metal substrate is removed. The photoresist film is removed by softening with chemicals and cleaning with high pressure water.

Step 17: plating with an anti-oxidizing metal layer or coating with an organic solderability preservative (OSP).

Referring to FIG. 17, an exposed metal surface of the metal substrate surface from which the photoresist film has been removed in step 16 is plated with the anti-oxidizing metal layer, such as gold, nickel-gold, nickel-palladium-gold or tin, or is coated with the organic solderability preservative (OSP).

Second embodiment: a single wiring layer, a single flip chip and a single-turn lead (2).

Referring to FIG. 39, it is a packaging-before-etching flip chip 3D system-in-package metal circuit board structure provided in the present disclosure, and the structure includes: a metal substrate frame 1; a die pad 2 and a lead 3 provided in a front surface of the metal substrate frame 1; a conductive pillar 4 provided on the front surface of the lead 3, a chip 5 flipped on the front surface of the die pad 2 and a lead 3 via underfills; a molding material or epoxy resin 7 with which a periphery region of the die pad 2, the lead 3, the conductive pillar 4, and the chip 5 is encapsulated, with the molding material or epoxy resin 7 being flushed with the top of the conductive pillar 4; a high conductivity metal layer 8 provided on the back surface of the die pad 2 and the lead 3; green paint or photosensitive non-conductive adhesive 9 filling between the high conductivity metal layers 8; an anti-oxidizing layer 6 provided on the surface of the metal substrate frame 1, the conductive pillar 4 and the high conductivity metal layer 8 exposed from the molding material or epoxy resin 7 and green paint or photosensitive non-conductive adhesive material 9.

The differences between the second embodiment and the first embodiment are that: the conductive pillar 4 according to the second embodiment is used as an inner lead actually, and the subsequent molding progress is performed on the front surface of the metal substrate frame; while the conductive pillar 4 according to the first embodiment is used as an outer lead actually, the subsequent molding progress is performed on the back surface of the metal substrate frame.

A processing method for manufacturing a packaging-before-etching flip chip 3D system-in-package metal circuit board structure is described as follows.

Step 1: providing a metal substrate.

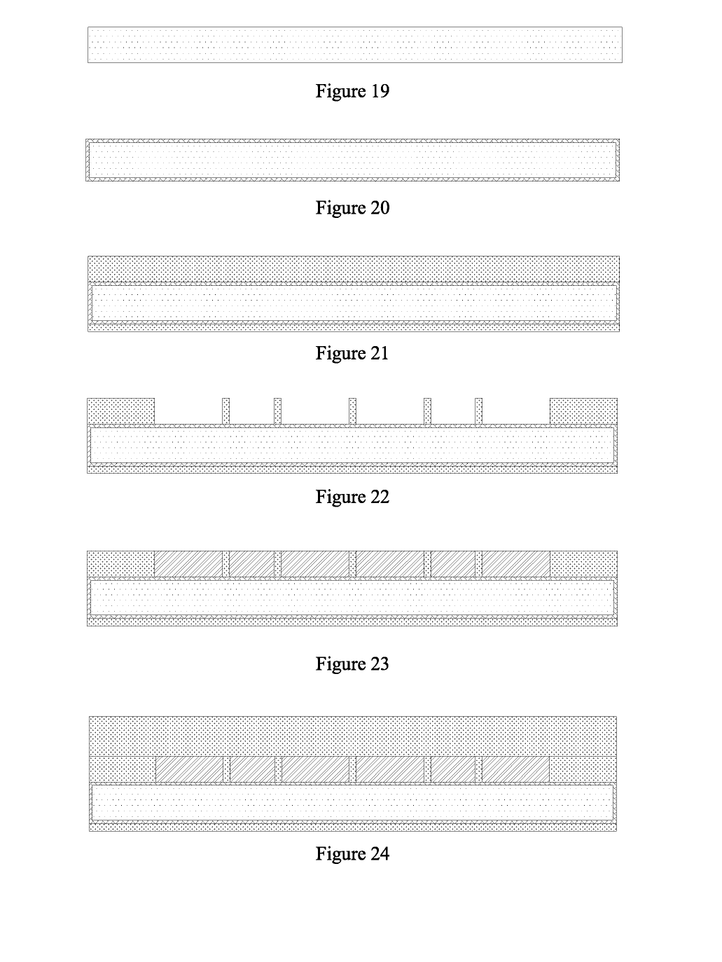

Referring to FIG. 19, the metal substrate having suitable thickness is provided. The metal substrate may be made from copper material, iron material, zinc plating material, stainless steel material, aluminum material, metallic material which may achieve conductive function or the like. The thickness of the metal substrate may be chosen depending on product properties.

Step 2: pre-plating the surface of the metal substrate with a copper material.

Referring to FIG. 20, the surface of the metal substrate is pre-plated with a layer of copper material. The copper layer has a thickness of 2 μm to 10 μm, which may also be thinned or thickened depending on a function requirement. The plating may be electrolytic plating, and chemical deposition may also be adopted.

Step 3: attaching a photoresist film.

Referring to FIG. 21, a front surface and a back surface of the metal substrate which have been pre-plated with the copper material in step 2 are respectively attached with the photoresist film which can be exposed and developed, in order to manufacture a metal wiring pattern later. The photoresist film may be a dry-type photoresist film or a wet-type photoresist film.

Step 4: removing a part of the photoresist film on the front surface of the metal substrate.

Referring to FIG. 22, the front surface of the metal substrate which has been attached with the photoresist film in step 3 is exposed and developed with a pattern using an exposure and development equipment, and the part of the photoresist film in the pattern is removed, so as to expose an region of the front surface of the metal substrate to be plated with a metal wiring layer later.

Step 5: plating with the metal wiring layer.

Referring to FIG. 23, the region of the front surface of the metal substrate from which the part of the photoresist film has been removed in step 4 is plated with the metal wiring layer, so that a die pad and a lead are formed on the front surface of the metal substrate. The metal wiring layer may be made from copper, aluminum, nickel, silver, gold, copper-silver, nickel-gold, nickel-palladium-gold, metallic materials which may achieve a conductive function or the like. The metal wiring layer has a thickness of 5 μm to 20 μm. The plated thickness may be varied depending on product properties. The plating may be electrolytic plating, and chemical deposition may also be adopted.

Step 6: attaching a photoresist film.

Referring to 24, the front surface of the metal substrate which has been plated with the metal wiring layer in step 5 is attached with the photoresist film which can be exposed and developed, in order to manufacture a conductive pillar later. The photoresist film may be a dry-type photoresist film or a wet-type photoresist film.

Step 7: removing a part of the photoresist film on the front surface of the metal substrate.

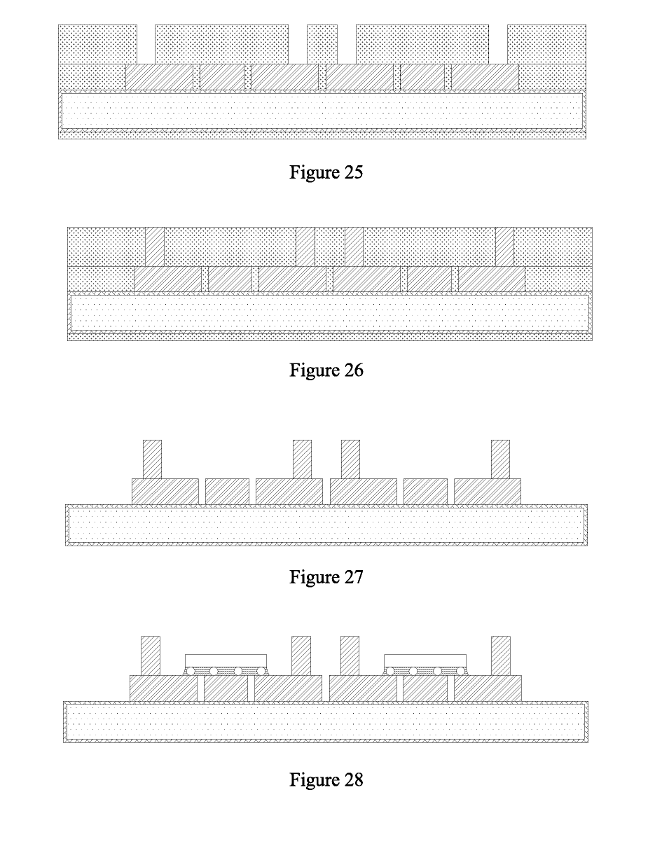

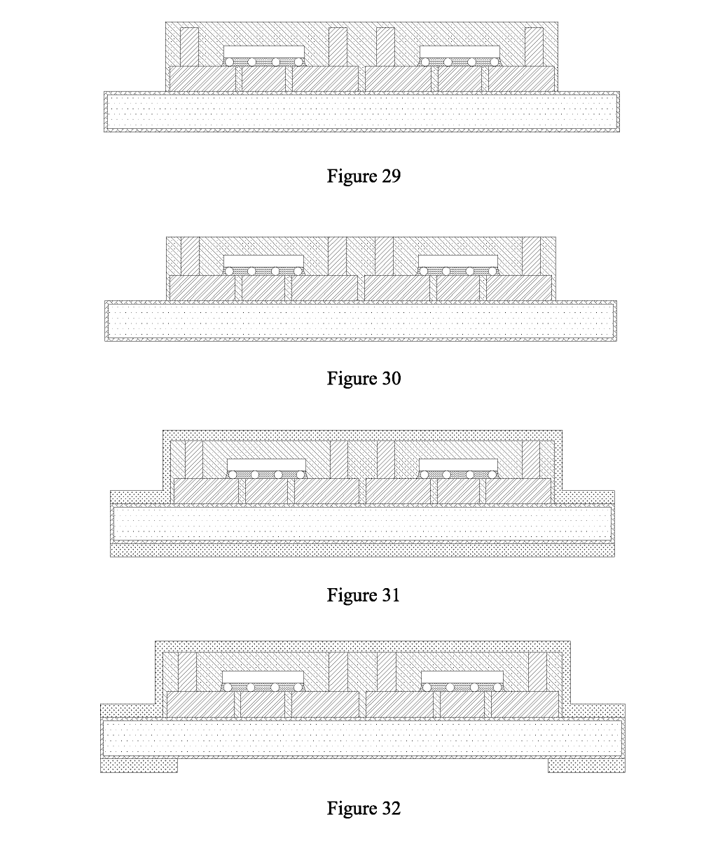

Referring to FIG. 25, the front surface of the metal substrate which has been attached with the photoresist film in step 6 is exposed and developed with a pattern using an exposure and development equipment, and the part of the photoresist film in a pattern is removed, so as to expose a region of the front surface of the metal substrate to be plated with a conductive pillar later.

Step 8: plating with the conductive pillar.

Referring to FIG. 26, the region of the front surface of the metal substrate from which a part of the photoresist film has been removed in step 7 is plated with the conductive pillar. The conductive pillar may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 9: removing the photoresist film.

Referring to FIG. 27, the photoresist film on the surface of the metal substrate is removed. The photoresist film may be removed by softening with chemicals and cleaning with high pressure water.

Step 10: bonding die.

Referring to FIG. 28, a chip is flipped on a front surface of the die pad and the lead formed in step 5 via underfills.

Step 11: molding with an epoxy resin.

Referring to FIG. 31, the molding with the epoxy resin for protecting is performed on the front surface of the metal substrate after the bonding die has been performed. The epoxy resin material may be selected to be an epoxy resin with or without filler depending on product properties.

Step 12: grinding a surface of the epoxy resin.

Referring to FIG. 30, the surface of the epoxy resin is ground after the molding with the epoxy resin has been performed in step 11.

Step 13: attaching a photoresist film.

Referring to FIG. 31, the front surface and the back surface of the metal substrate are attached with the photoresist film which can be exposed and developed after the surface of the epoxy resin has been ground in step 12.

Step 14: removing a part of the photoresist film on the back surface of the metal substrate.

Referring to FIG. 32, the back surface of the metal substrate, which has been attached with the photoresist film in step 13, is exposed and developed with a pattern using an exposure and development equipment, and the part of the photoresist film in the pattern is removed, so as to expose a region of the back surface of the metal substrate to be etched later.

Step 15: etching.

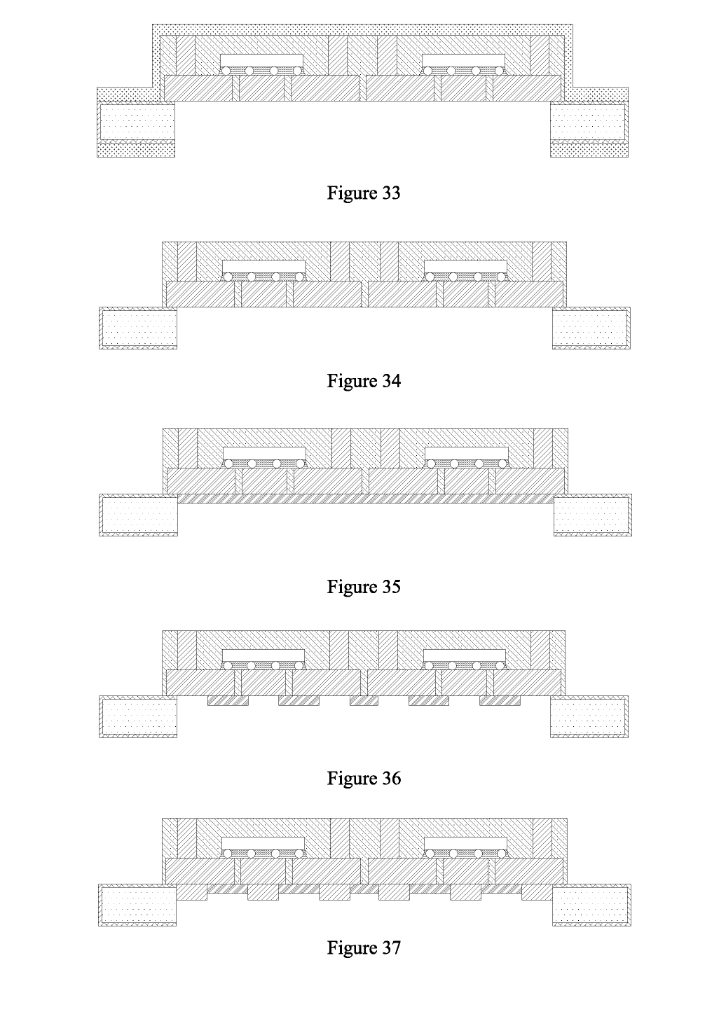

Referring to FIG. 33, chemical etching is performed in the region of the back surface of the metal substrate from which the part of the photoresist film has been removed in step 14.

Step 16: removing the photoresist film.

Referring to FIG. 34, the photoresist film on the surface of the metal substrate is removed. The photoresist film is removed by softening with chemicals and cleaning with high pressure water.

Step 17: coating the back surface of the metal substrate with green paint.

Referring to FIG. 35, the back surface of the metal substrate from which the photoresist film has been removed in step 16 is coated with green paint.

Step 18: exposing and developing to form a window.

Referring to FIG. 36, the green paint with which the back surface of the metal substrate is coated is exposed and developed using an exposure and development equipment to form the window, so as to expose a region of the back surface of the metal substrate to be plated with a high conductivity metal layer later.

Step 19: plating with the high conductivity metal layer.

Referring to FIG. 37, a region of the window formed in the green paint on the back surface of the metal substrate in the Sep 18 is plated with the high conductivity metal layer.

Step 20: plating with an anti-oxidizing metal layer or coating with an organic solderability preservative (OSP).

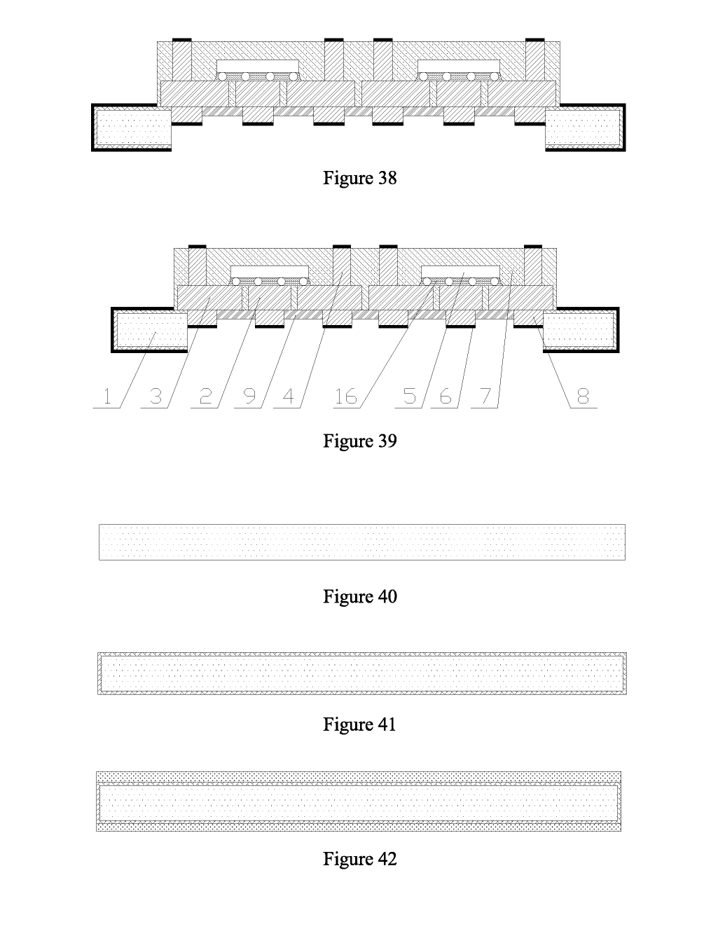

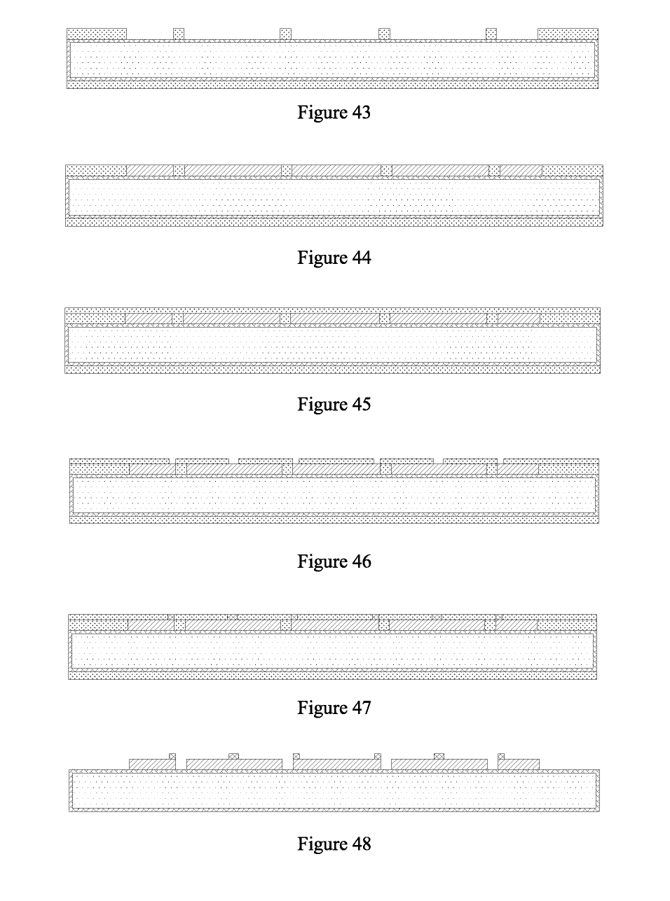

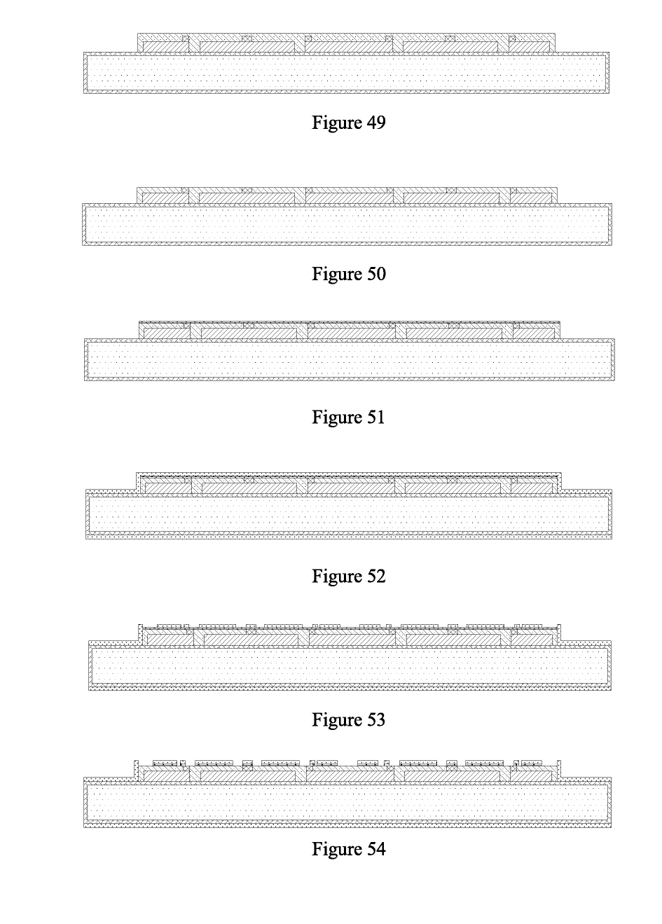

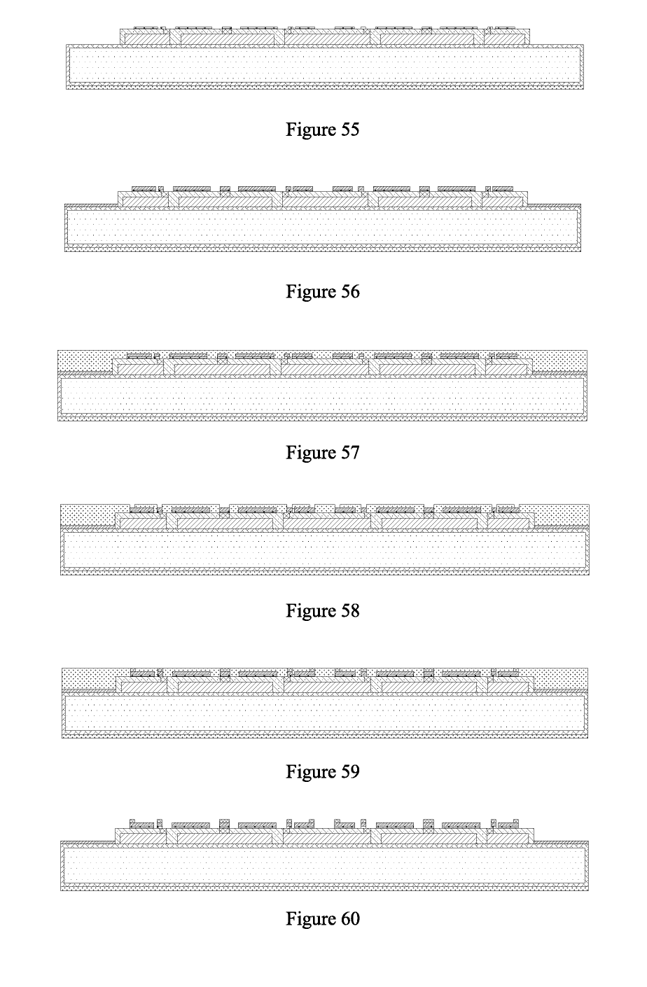

Referring to FIG. 38, an exposed metal surface of the metal substrate surface is plated with the anti-oxidizing metal layer, such as gold, nickel-gold, nickel-palladium-gold or tin, or coated with the organic solderability preservative (OSP).

Third embodiment: multiple wiring layers, a single flip chip and a single-turn lead.

Referring to FIG. 81, it is a packaging-before-etching flip chip 3D system-in-package metal circuit board structure provided in the present disclosure, and the structure includes: a metal substrate frame 1; a die pad 2 and a lead 3 provided in a front surface of the metal substrate frame 1; a conductive pillar 4 provided on the front surface of the lead 3; a chip 5 flipped on the front surface of the die pad 2 and the lead 3 by underfills; a molding material or epoxy resin 7 with which a periphery region of the die pad 2, the lead 3, the conductive pillar 4, and the chip 5 is encapsulated, with the molding material or epoxy resin 7 being flushed with the top of the conductive pillar 4; an anti-oxidizing layer 6 provided on the surface of the metal substrate frame 1, the die pad 2, the lead 3 and the conductive pillar 4 exposed from the molding material or epoxy resin 7.

The third embodiment differs from the first embodiment in that the die pad 2 and the lead 3 are both formed of the multiple metal wiring layers, and the metal wiring layers are connected with each other via a conductive pillar.

A processing method for manufacturing a packaging-before-etching flip chip 3D system-in-package metal circuit board structure is described as follows.

Step 1: providing a metal substrate.

Referring to FIG. 40, the metal substrate having suitable thickness is provided. The metal substrate may be made from copper material, iron material, zinc plating material, stainless steel material, aluminum material or metallic or nonmetallic material which may achieve a conductive function. The thickness of the metal substrate may be chosen depending on product properties.

Step 2: pre-plating the surface of the metal substrate with a copper material.

Referring to FIG. 41, the surface of the metal substrate is pre-plated with a layer of copper material. The copper layer has a thickness of 2 μm to 10 μm, which may also be thinned or thickened depending on a function requirement. The plating may be electrolytic plating, and chemical deposition may also be adopted.

Step 3: attaching a photoresist film.

Referring to FIG. 42, a front surface and a back surface of the metal substrate which have been pre-plated with the copper material in step 2 are respectively attached with the photoresist film which can be exposed and developed, in order to manufacture a metal wiring pattern later. The photoresist film may be a dry-type photoresist film or a wet-type photoresist film.

Step 4: removing a part of the photoresist film on the front surface of the metal substrate.

Referring to FIG. 43, the front surface of the metal substrate which has been attached with the photoresist film in step 3 is exposed and developed with a pattern using an exposure and development equipment, and the part of the photoresist film in the pattern is removed, so as to expose a region of the front surface of the metal substrate to be plated with a first metal wiring layer later.

Step 5: plating with the first metal wiring layer.

Referring to FIG. 44, the region of the front surface of the metal substrate from which the part of the photoresist film has been removed in step 4 is plated with the first metal wiring layer. The metal wiring layer may be made from copper, aluminum, nickel, silver, gold, copper-silver, nickel-gold, nickel-palladium-gold or the like. The plating may be electrolytic plating, and chemical deposition may also be adopted.

Step 6: attaching a photoresist film.

Referring to 45, the front surface of the metal substrate which has been plated with the first metal wiring layer in step 5 is attached with the photoresist film which can be exposed and developed, in order to manufacture a metal wiring pattern later. The photoresist film may be a dry-type photoresist film or a wet-type photoresist film.

Step 7: removing a part of the photoresist film on the front surface of the metal substrate.

Referring to FIG. 46, the front surface of the metal substrate which has been attached with the photoresist film in step 6 is exposed and developed with a pattern using an exposure and development equipment, and the part of the photoresist film in a pattern is removed, so as to expose a region of the front surface of the metal substrate to be plated with a second metal wiring layer later.

Step 8: plating with the second metal wiring layer.

Referring to FIG. 47, the region of the front surface of the metal substrate from which a part of the photoresist film has been removed in step 7 is plated with the second wiring layer serving as a conductive pillar for connecting the first metal wiring layer to a third metal wiring layer. The second metal wiring layer may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 9: removing the photoresist film.

Referring to FIG. 48, the photoresist film on the surface of the metal substrate is removed. The photoresist film may be removed by softening with chemicals and cleaning with high pressure water.

Step 10: attaching a non-conductive adhesive film.

Referring to FIG. 49, a region of the front surface of the metal substrate in which the wiring layer is provided is attached with a layer of non-conductive adhesive film, in order to insulate the first metal wiring layer from the third metal wiring layer. The non-conductive adhesive film may be attached with by a conventional rolling machine, or in a vacuum environment to prevent air residual during the attaching. The non-conductive adhesive film is mainly a attaching type non-conductive adhesive film made from thermosetting epoxy resin. And the epoxy resin may be an epoxy resin with or without filler depending on product properties.

Step 11: grinding the surface of the non-conductive adhesive film.

Referring to FIG. 50, the surface of the non-conductive adhesive film is ground after the attaching non-conductive adhesive film has been performed in step 10, in order to expose the second metal wiring layer, maintain the flatness of the non-conductive adhesive film and the second metal wiring layer and control the thickness of the non-conductive adhesive film.

Step 12: performing metallization pre-treatment on the surface of the non-conductive adhesive film.

Referring to FIG. 51, the metallization pre-treatment is performed on the surface of the non-conductive adhesive film, such that a layer of metalized polymer material is adhered onto the surface of the non-conductive adhesive film in order to provide a surface serving as a catalytic converter for plating with a metallic material later, or roughening treatment is performed on the surface of the non-conductive adhesive film. The metalized polymer material may be adhered by spraying, plasma oscillation, surface roughening, or the like, and then it is dried.

Step 13: attaching a photoresist film.

Referring to FIG. 52, the front surface and the back surface of the metal substrate are attached with the photoresist film which can be exposed and developed after the metallization pre-treatment has been performed in step 12, in order to manufacture a metal wiring pattern later. The photoresist film may be a dry-type photoresist film or a wet-type photoresist film.

Step 14: removing a part of the photoresist film on the front surface of the metal substrate.

Referring to FIG. 53, the front surface of the metal substrate which has been attached with the photoresist film in step 13, is exposed and developed with a pattern using an exposure and development equipment, and the part of the photoresist film in pattern is removed, so as to expose a region of the front surface of the metal substrate to be etched later.

Step 15: etching.

Referring to FIG. 54, the region of the front surface of the metal substrate from which the part of the photoresist film has been removed in step 14 is etched, in order to etch and remove the metallization pre-treatment region not to be plated with a third metal wiring layer later using the etching technology. The processing method for etching may be an etching process using copper chloride or iron chloride.

Step 16: removing the photoresist film.

Referring to FIG. 55, the photoresist film on the front surface of the metal substrate is removed. The photoresist film may be removed by softening with chemicals and cleaning with high pressure water.

Step 17: plating with the third metal wiring layer.

Referring to FIG. 56, the remaining metallization pre-treatment region of the front surface of the metal substrate on which the etching has been performed in step 15 is plated with the third metal wiring layer. The third metal wiring layer may be made from copper, aluminum, nickel, silver, gold, copper-silver, nickel-gold, nickel-palladium-gold or the like. The plating may be electrolytic plating, and chemical deposition may also be adopted.

Step 18: attaching a photoresist film.

Referring to FIG. 57, the front surface of the metal substrate which has been plated with the third metal wiring layer in step 17 is attached with the photoresist film adapted to expose and develop, in order to manufacture a metal wiring pattern later. The photoresist film may be a dry-type photoresist film or a wet-type photoresist film.

Step 19: removing a part of the photoresist film on the front surface of the metal substrate.

Referring to FIG. 58, the front surface of the metal substrate which has been attached with the photoresist film in step 18 is exposed and developed with a pattern using an exposure and development equipment, and the part of the photoresist film in the pattern is removed, so as to expose a region of the front surface of the metal substrate to be plated with a fourth metal wiring layer.

Step 20: plating with the fourth metal wiring layer.

Referring to FIG. 59, the region of the front surface of the metal substrate from which the part of the photoresist film has been removed in step 19 is plated with the fourth metal wiring layer serving as a conductive pillar for connecting the third metal wiring layer to the fifth metal wiring layer. The fourth metal wiring layer may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 21: removing the photoresist film.

Referring to FIG. 60, the photoresist film on the front surface of the metal substrate is removed. The photoresist film may be removed by softening with chemicals and cleaning with high pressure water.

Step 22: attaching a non-conductive adhesive film.

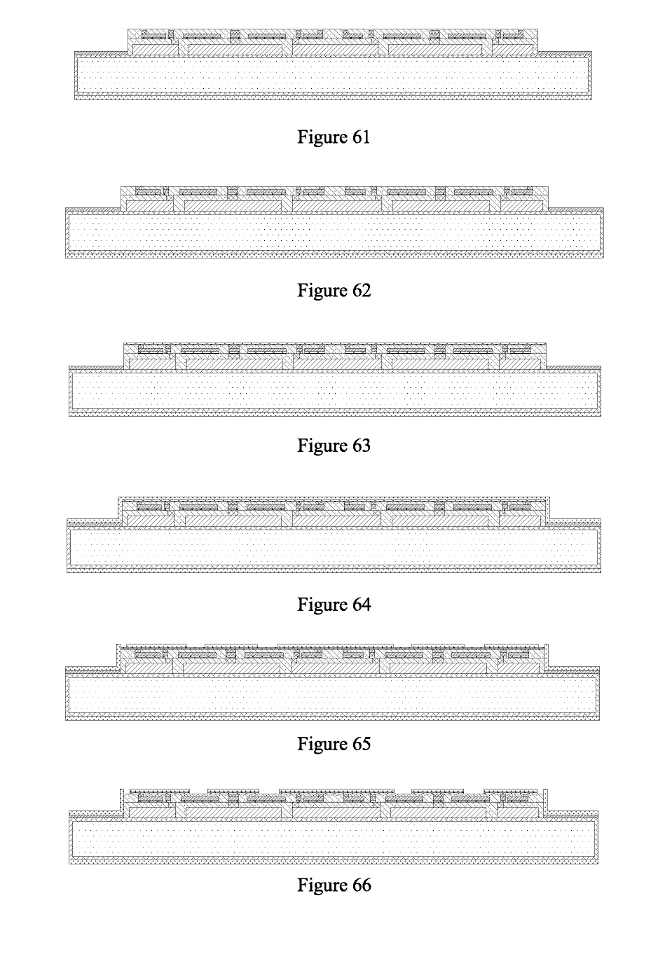

Referring to FIG. 61, a region of the front surface of the metal substrate in which the wiring layer is provided is attached with a layer of non-conductive adhesive film, in order to insulate the third metal wiring layer from the fifth metal wiring layer. The non-conductive adhesive film may be attached with by a conventional rolling machine, or in a vacuum environment to prevent air residual during the attaching. The non-conductive adhesive film is mainly a attaching type non-conductive adhesive film made from thermosetting epoxy resin. And the epoxy resin may be an epoxy resin with or without filler depending on product properties.

Step 23: grinding a surface of the non-conductive adhesive film.

Referring to FIG. 62, the surface of the non-conductive adhesive film is ground after the attaching the non-conductive adhesive film has been performed in step 22, in order to expose the fourth metal wiring layer, maintain the flatness of the non-conductive adhesive film and the fourth metal wiring layer and control the thickness of the non-conductive adhesive film.

Step 24: performing metallization pre-treatment on a surface of the non-conductive adhesive film.

Referring to FIG. 63, the metallization pre-treatment is performed on the surface of the non-conductive adhesive film, such that a layer of metalized polymer material is adhered onto the surface of the non-conductive adhesive film in order to provide a surface serving as a catalytic converter for plating with a metallic material later, or roughening treatment is performed on the surface of the non-conductive adhesive film. The metalized polymer material may be adhered by spraying, plasma oscillation, surface roughening, or the like, and then it is dried.

Step 25: attaching a photoresist film.

Referring to FIG. 64, the front surface and the back surface of the metal substrate on which the metallization pre-treatment has been performed in step 24 are attached with the photoresist film which can be exposed and developed, in order to manufacture a metal wiring pattern later. The photoresist film may be a dry-type photoresist film or a wet-type photoresist film.

Step 26: removing a part of the photoresist film on the front surface of the metal substrate.

Referring to FIG. 65, the front surface of the metal substrate which has been attached with the photoresist film in step 25 is exposed and developed with a pattern using an exposure and development equipment, and the part of the photoresist film in the pattern is removed, so as to expose a region of the front surface of the metal substrate to be etched later.

Step 27: etching.

Referring to FIG. 66, the region of the front surface of the metal substrate from which the part of the photoresist film has been removed in step 26 is etched, in order to etch and remove the metallization pre-treatment region not to be plated with a fifth metal wiring layer later using the etching technology. The processing method for etching may be an etching process using copper chloride or iron chloride.

Step 28: removing the photoresist film.

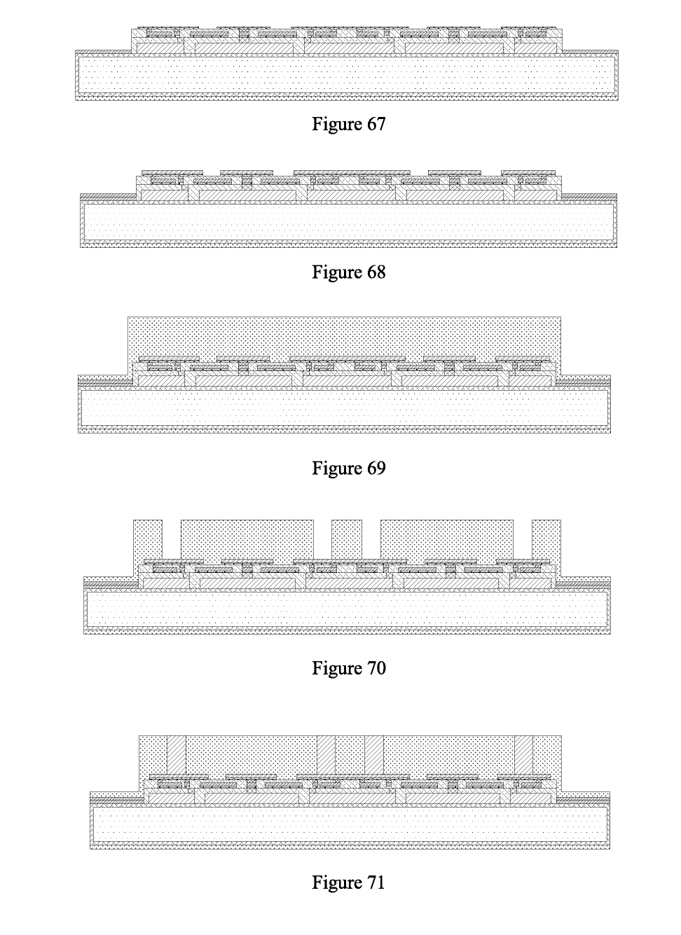

Referring to FIG. 67, the photoresist film on the surface of the metal substrate is removed. The photoresist film may be removed by softening with chemicals and cleaning with high pressure water.

Step 29: plating with the fifth metal wiring layer.

Referring to FIG. 68, the remaining metallization pre-treatment region of the front surface of the metal substrate on which the etching has been performed in step 27 is plated with the fifth metal wiring layer, so that a die pad and a lead are formed on the front surface of the metal substrate. The fifth metal wiring layer may be made from copper, aluminum, nickel, silver, gold, copper-silver, nickel-gold or nickel-palladium-gold. The plating may be electrolytic plating, and chemical deposition may also be adopted.

Step 30: attaching a photoresist film.

Referring to FIG. 69, the front surface of the metal substrate which has been plated with the fifth metal wiring layer in step 29 is attached with the photoresist film which can be exposed and developed, in order to manufacture a conductive pillar later. The photoresist film may be a dry-type photoresist film or a wet-type photoresist film.

Step 31: removing a part of the photoresist film on the front surface of the metal substrate.

Referring to FIG. 70, the front surface of the metal substrate which has been attached with the photoresist film in step 30 is exposed and developed with a pattern using an exposure and development equipment, and the part of the photoresist film in the pattern is removed, so as to expose a region of the front surface of the metal substrate to be plated with conductive pillars.

Step 32: plating with the conductive pillar.

Referring to FIG. 71, the region of the front surface of the metal substrate from which the part of the photoresist film has been removed in step 31 is plated with the conductive pillar. The material of the conductive pillar may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 33: removing the photoresist film.

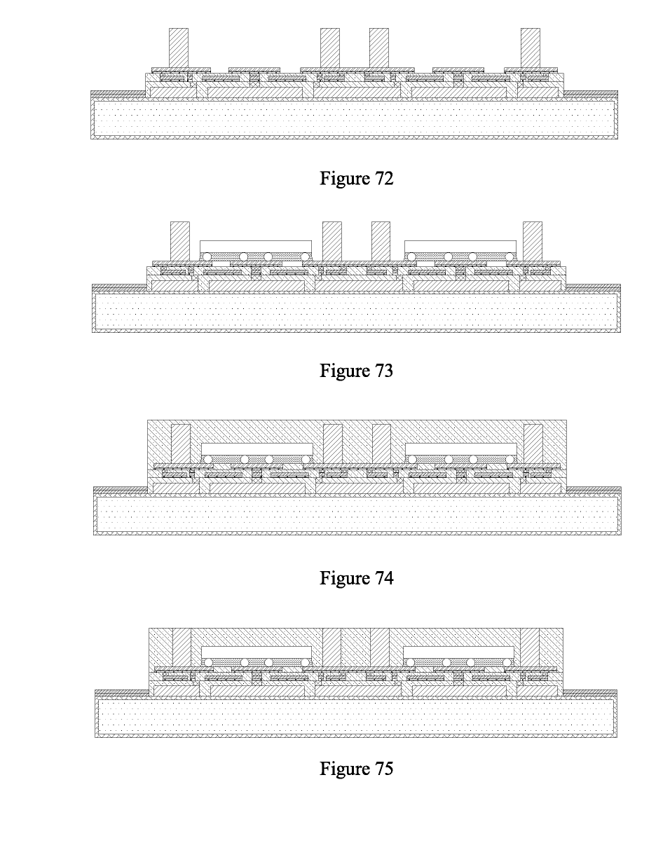

Referring to FIG. 72, the photoresist film on the surface of the metal substrate is removed. The photoresist film may be removed by softening with chemicals and cleaning with high pressure water.

Step 34: bonding die.

Referring to FIG. 73, a chip is flipped on a front surface of the die pad and the lead formed in step 29 by underfills.

Step 35: molding with epoxy resin.

Referring to FIG. 74, the molding with the epoxy resin for protecting is performed on the front surface of the metal substrate after the bonding die has been performed. The epoxy resin material may be selected to be an epoxy resin with or without filler depending on product properties.

Step 36: grinding a surface of the epoxy resin.

Referring to FIG. 75, the surface of the epoxy resin is ground after the molding with the epoxy resin has been performed in step 35.

Step 37: attaching a photoresist film.

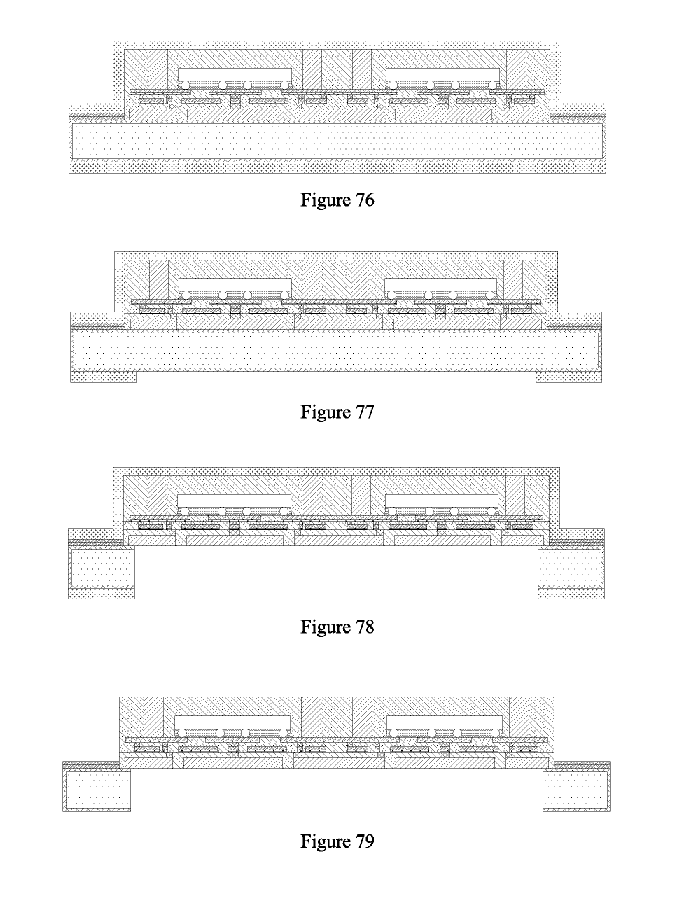

Referring to FIG. 76, a front surface and a back surface of the metal substrate are attached with the photoresist film which can be exposed and developed after the surface of the epoxy resin has been ground in step 36.

Step 38: removing a part of the photoresist film on the back surface of the metal substrate.

Referring to FIG. 77, the back surface of the metal substrate which has been attached with the photoresist film in step 37 is exposed and developed with a pattern using an exposure and development equipment, and the part of the photoresist film in the pattern is removed, so as to expose a region of the back surface of the metal substrate to be etched later.

Step 39: etching.

Referring to FIG. 78, chemical etching is performed in the region of the back surface of the metal substrate from which the part of the photoresist film has been removed in step 38.

Step 40: removing the photoresist film.

Referring to FIG. 79, the photoresist film on the surface of the metal substrate is removed. The photoresist film may be removed by softening with chemicals and cleaning with high pressure water.

Step 41: plating with an anti-oxidizing metal layer or coating with an organic solderability preservative (OSP).

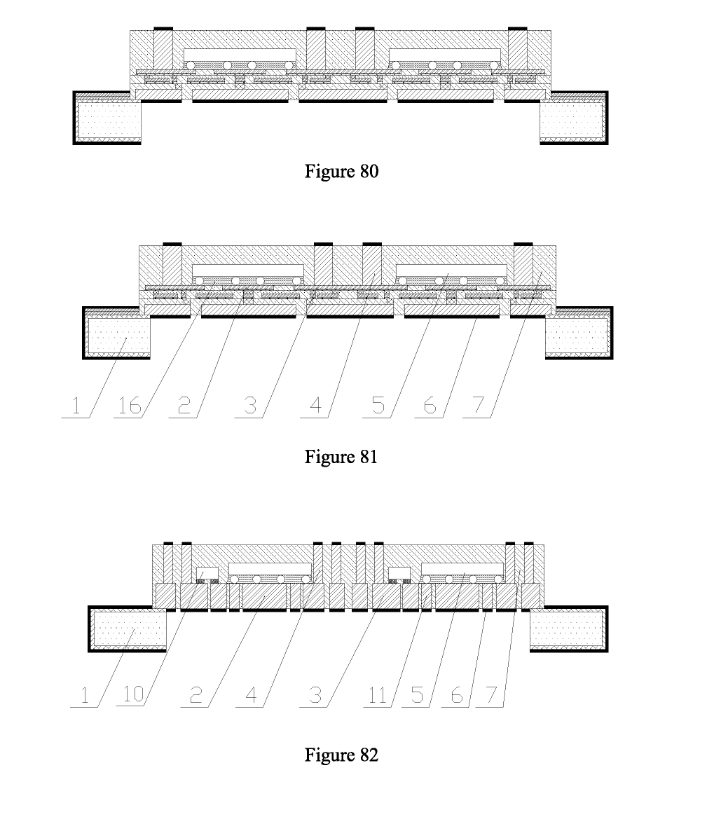

Referring to FIG. 80, the exposed metal surface of the metal substrate surface from which the photoresist film has been removed in step 41 is plated with the anti-oxidizing metal layer, such as gold, nickel-gold, nickel-palladium-gold or tin, or is coated with the organic solderability preservative (OSP).

Fourth embodiment: a single flip chip, multi-turn leads, a passive device and an electrostatic discharge coil.

Referring to FIG. 82, the fourth embodiment differs from the first embodiment in that multi-turn conductive pillars 4 are provided; a passive device 10 is connected across a front surface of the leads 3; the electrostatic discharge coil 11 is provided between the die pad 2 and the lead 3; and a chip 5 is flipped on a front surface of the die pad 2, the lead 3 and the electrostatic discharge coil 11.

Fifth embodiment: multiple chips provided in a plane.

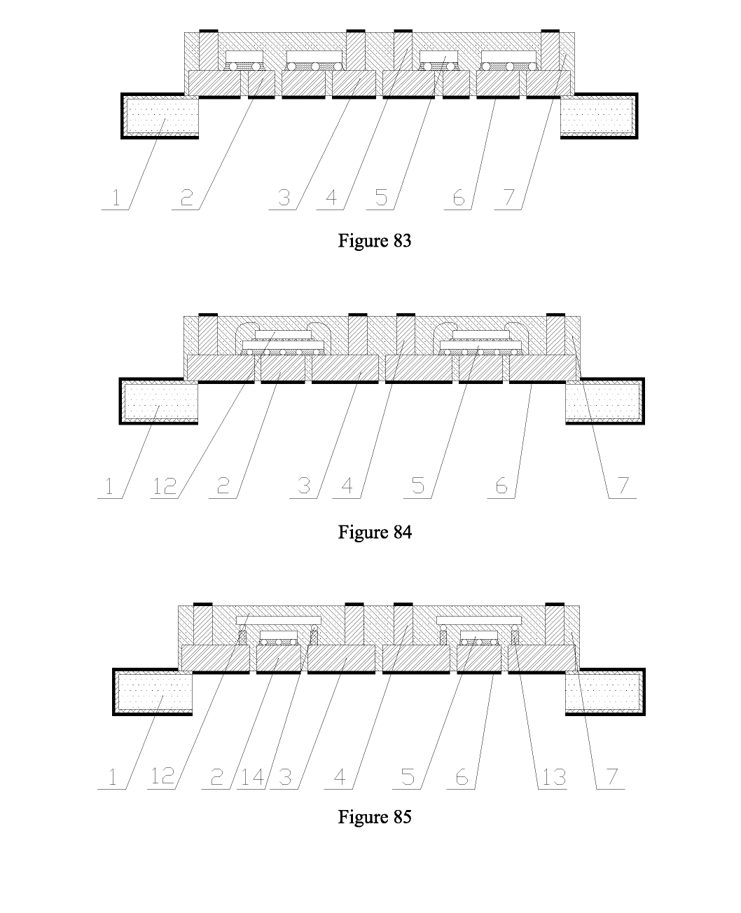

Referring to FIG. 83, the fifth embodiment differs from the first embodiment in that a plurality of chips 5 are flipped on die pads 2 and the leads 3.

Sixth embodiment: multiple chips stack with a chip being normally mounted on a flip chip.

Referring to FIG. 84, the sixth embodiment differs from the first embodiment in that a second chip 12 is mounted normally on the back surface of the chip 5 by conductive or nonconductive adhesive material; and the second chip 12 is connected to the lead 3 via a metal wire 15.

Seventh embodiment: multiple chips stack with a flip chip being mounted on another flip chip.

Referring to FIG. 85, the seventh embodiment differs from the first embodiment in that a second conductive pillar 13 is provided on the front surface of the lead 3; a second chip 12 is flipped on the second conductive pillar 13 by a conductive material 14; the second chip 12 is located above the chip 5; and the second conductive pillar 13 and the second chip 12 are located inside the molding material 7.

The second chip 12 may be replaced by the passive device 10.

Eighth embodiment: a single flip chip without a die pad.

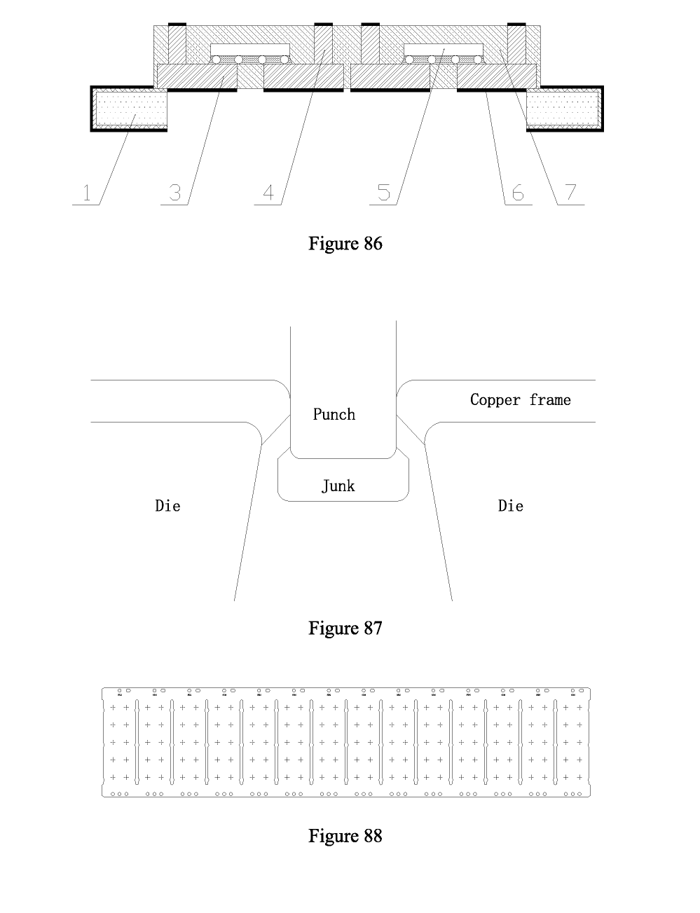

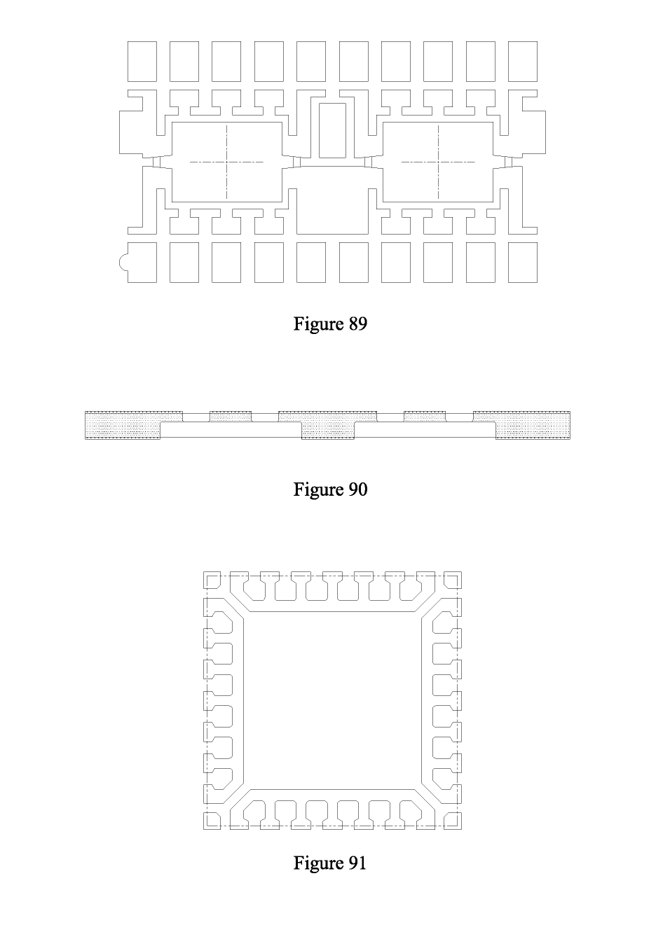

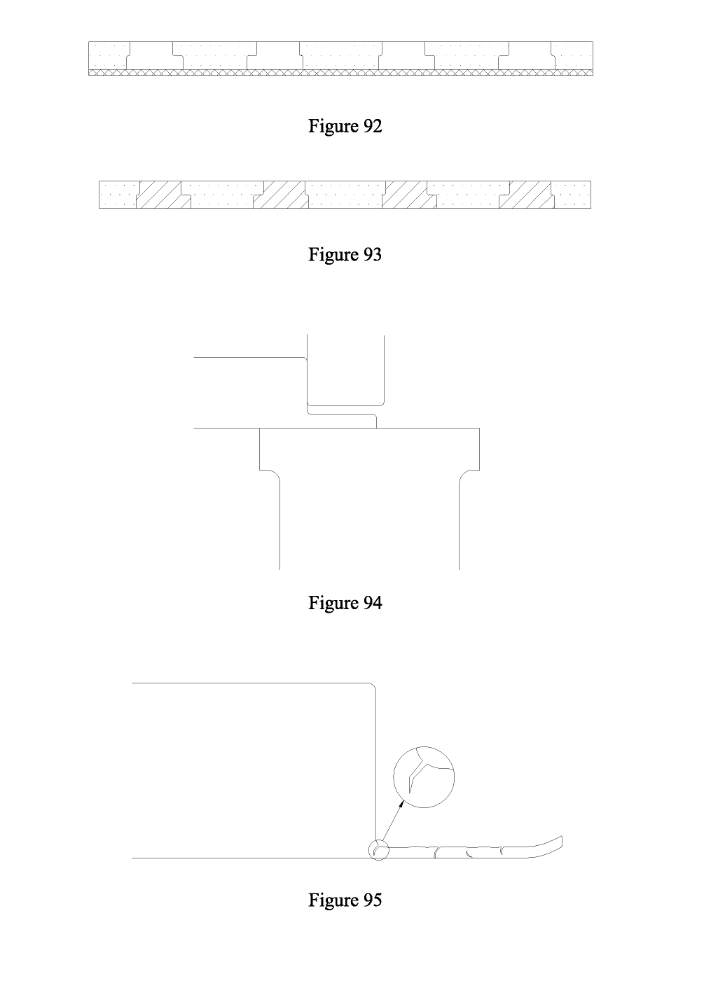

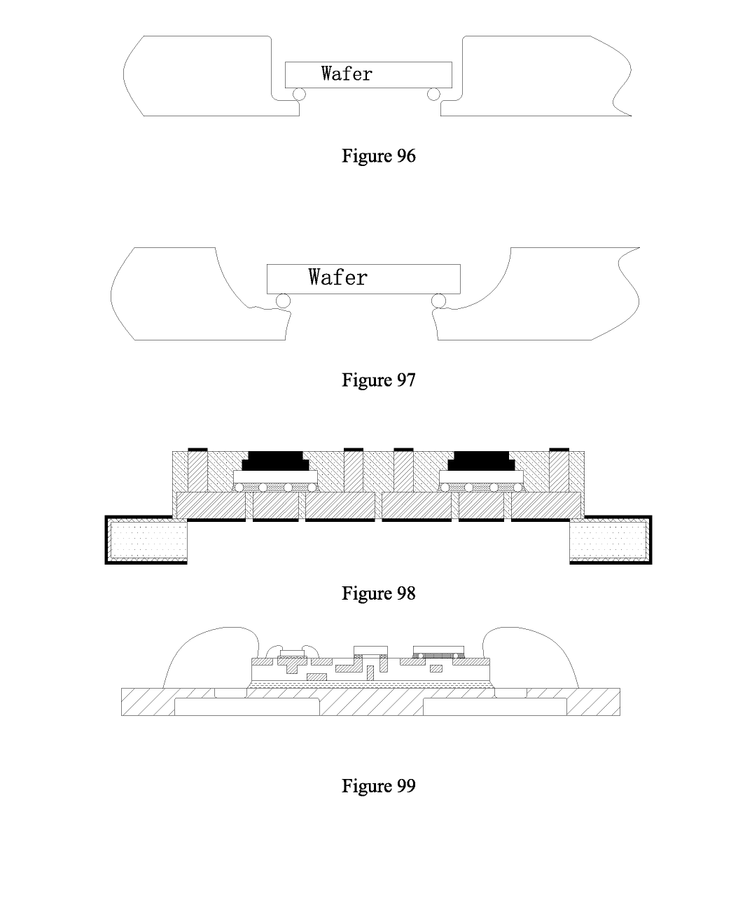

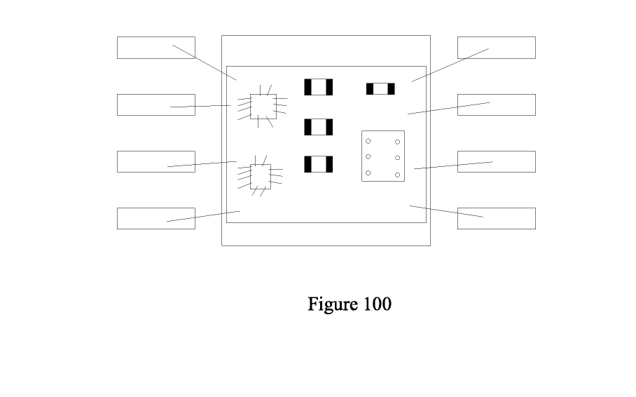

Referring to FIG. 86, the eighth embodiment differs from the first embodiment in that the metal circuit board structure does not include a die pad 2; and the chip 5 is flipped on the front surfaces of the leads 3.

What is claimed is:

1. A method for manufacturing a packaging-before-etching flip chip 3D system-in-package metal circuit board structure, comprising:
step 1: providing a metal substrate;
step 2: pre-plating a surface of the metal substrate with a copper material,
wherein the surface of the metal substrate is pre-plated with a layer of copper material;
step 3: attaching a photoresist film,
wherein a front surface and a back surface of the metal substrate which have been pre-plated with the copper material in step 2 are respectively attached with the photoresist film which can be exposed and developed;
step 4: removing a part of the photoresist film on the front surface of the metal substrate, wherein the front surface of the metal substrate, which has been attached with the photoresist film in step 3 is exposed and developed with a pattern using an exposure and development equipment, and the part of the photoresist film in the pattern is removed, so as to expose a region of the front surface of the metal substrate to be plated with a metal wiring layer later;
step 5: plating with the metal wiring layer,
wherein the region of the front surface of the metal substrate from which the part of the photoresist film has been removed in step 4 is plated with the metal wiring layer, so that a die pad and a lead are formed on the front surface of the metal substrate;
step 6: attaching a photoresist film,
wherein the front surface of the metal substrate which has been plated with the metal wiring layer in step 5 is attached with the photoresist film which can be exposed and developed;
step 7: removing a part of the photoresist film on the front surface of the metal substrate,
wherein the front surface of the metal substrate which has been attached with the photoresist film in step 6 is exposed and developed with a pattern using an exposure and development equipment, and the part of the photoresist film in a pattern is removed, so as to expose a region of the front surface of the metal substrate to be plated with a conductive pillar later;
step 8: plating with the conductive pillar,
wherein the region of the front surface of the metal substrate from which the part of the photoresist film has been removed in step 7 is plated with the conductive pillar;
step 9: removing the photoresist film,
wherein the photoresist film on the surface of the metal substrate is removed;
step 10: bonding die,
wherein a chip is flipped on a front surface of the die pad and the lead formed in step 5 by underfills;
step 11: molding with an epoxy resin,
wherein the molding with the epoxy resin for protecting is performed on the front surface of the metal substrate after the bonding die has been performed;
step 12: grinding a surface of the epoxy resin,
wherein the surface of the epoxy resin is ground after the molding with the epoxy resin has been performed in step 12;
step 13: attaching a photoresist film,
wherein the front surface and the back surface of the metal substrate are attached with the photoresist film which can be exposed and developed after the surface of the epoxy resin has been ground in step 12;
step 14: removing a part of the photoresist film on the back surface of the metal substrate,
wherein the back surface of the metal substrate, which has been attached with the photoresist film in step 13, is exposed and developed with a pattern using an exposure and development equipment, and the part of the photoresist film in the pattern is removed, so as to expose a region of the back surface of the metal substrate to be etched later;
step 15: etching,
wherein chemical etching is performed in the region of the back surface of the metal substrate from which the part of the photoresist film has been removed in step 14;
step 16: removing the photoresist film,
wherein the photoresist film on the surface of the metal substrate is removed, the photoresist film is removed by softening with chemicals and cleaning with high pressure water; and
step 17: plating with an anti-oxidizing metal layer or coating with an organic solderability preservative,
wherein an exposed metal surface of the metal substrate surface from which the photoresist film has been removed in step 17 is plated with the anti-oxidizing metal layer or is coated with the organic solderability preservative.

2. (canceled)

3. A method for manufacturing a packaging-before-etching flip chip 3D system-in-package metal circuit board structure, comprising:
step 1: providing a metal substrate;
step 2: pre-plating the surface of the metal substrate with a copper material,
wherein the surface of the metal substrate is pre-plated with a layer of copper material;
step 3: attaching a photoresist film,
wherein a front surface and a back surface of the metal substrate which have been pre-plated with the copper material in step 2 are attached with the photoresist film which can be exposed and developed;
step 4: removing a part of the photoresist film on the front surface of the metal substrate, wherein the front surface of the metal substrate which has been attached with the photoresist film in step 3 is exposed and developed with a pattern using an exposure and development equipment, and the part of the photoresist film in the pattern is removed, so as to expose a region of the front surface of the metal substrate to be plated with a first metal wiring layer later;
step 5: plating with the first metal wiring layer,
wherein the region of the front surface of the metal substrate from which the part of the photoresist film has been removed in step 4 is plated with the first metal wiring layer;
step 6: attaching a photoresist film,
wherein the front surface of the metal substrate which has been plated with the first metal wiring layer in step 5 is attached with the photoresist film which can be exposed and developed;
step 7: removing a part of the photoresist film on the front surface of the metal substrate,
wherein the front surface of the metal substrate which has been attached with the photoresist film in step 6 is exposed and developed with a pattern using an exposure and development equipment, and the part of the photoresist film in the pattern is removed, so as to expose a region of the front surface of the metal substrate to be plated with a second metal wiring layer later;
step 8: plating with the second metal wiring layer,
wherein the region of the front surface of the metal substrate from which the part of the photoresist film has been removed in step 7 is plated with the second metal wiring layer, which serves as a conductive pillar to connect the first metal wiring layer to a third metal wiring layer;
step 9: removing the photoresist film,
wherein the photoresist film on the surface of the metal substrate is removed;
step 10: attaching a non-conductive adhesive film,
wherein the front surface of the metal substrate is attached with a layer of non-conductive adhesive film;
step 11: grinding a surface of the non-conductive adhesive film,
wherein the surface of the non-conductive adhesive film is ground after the attaching the non-conductive adhesive film has been performed in step 10;
step 12: performing metallization pretreatment on the surface of the non-conductive adhesive film,
wherein the metallization pre-treatment is performed on the surface of the non-conductive adhesive film, so that a layer of metalized polymer material is adhered onto the surface of the non-conductive adhesive film, or roughening treatment is performed on the surface of the non-conductive adhesive film;
step 13: attaching a photoresist film,
wherein the front surface and the back surface of the metal substrate which have been metalized in step 12 are attached with the photoresist film which can be exposed and developed;
step 14: removing a part of the photoresist film on the front surface of the metal substrate,
wherein the front surface of the metal substrate, which has been attached with the photoresist film in step 13 is exposed and developed with a pattern using an exposure and development equipment, and the part of the photoresist film in the pattern is removed, so as to expose a region of the front surface of the metal substrate to be etched later;
step 15: etching,
wherein etching is performed in a region of the front surface of the metal substrate from which the part of the photoresist film has been removed in step 14;
step 16: removing the photoresist film,
wherein the photoresist film on the surface of the metal substrate is removed;
step 17: plating with a third metal wiring layer,
wherein a remaining metallization pre-treatment region of the front surface of the metal substrate on which the etching has been performed in step 15 is plated with the third wiring layer, so that a die pad and a lead are formed on the front surface of the metal substrate;
step 18: attaching a photoresist film,
wherein the front surface of the metal substrate which has been plated with the third metal wiring layer in step 17 is attached with the photoresist film which can be exposed and developed;
step 19: removing a part of the photoresist film on the front surface of the metal substrate,
wherein the front surface of the metal substrate, which has been attached with the photoresist film in step 18, is exposed and developed with a pattern using an exposure and development equipment, and the part of the photoresist film in the pattern is removed, so as to expose a region of the front surface of the metal substrate to be plated with a conductive pillar later;
step 20: plating with the conductive pillar,
wherein the region of the front surface of the metal substrate from which the part of the photoresist film has been removed in step 19 is plated with the conductive pillar;
step 21: removing the photoresist film,
wherein the photoresist film on the surface of the metal substrate is removed;
step 22: bonding die,
wherein a chip is flipped on a front surface of the die pad and the lead formed in step 17 by underfills;
step 23: molding with an epoxy resin,
wherein the molding with the epoxy resin for protecting is performed on the front surface of the metal substrate after the bonding die has been performed;
step 24: grinding a surface of the epoxy resin,
wherein the surface of the epoxy resin is ground after the molding with the epoxy resin has been performed in step 23;
step 25: attaching a photoresist film,
wherein the front surface and the back surface of the metal substrate are attached with the photoresist film which can be exposed and developed after the surface of the epoxy resin has been ground in step 24;
step 26: removing a part of the photoresist film on the back surface of the metal substrate,
wherein the back surface of the metal substrate which has been attached with the photoresist film in step 25 is exposed and developed with a pattern using an exposure and development equipment, and the part of the photoresist film in the pattern is removed, so as to expose a region of the back surface of the metal substrate to be etched later;
step 27: etching,
wherein chemical etching is performed in the region of the back surface of the metal substrate from which the part of the photoresist film has been removed in step 26;
step 28: removing the photoresist film,
wherein the photoresist film on the surface of the metal substrate is removed; and
step 29: plating with an anti-oxidizing metal layer or coating with an organic solderability preservative,
wherein an exposed metal surface of the metal substrate surface from which the photoresist film has been removed in step 28 is plated with the anti-oxidizing metal layer or is coated with the organic solderability preservative.

4. The method for manufacturing the packaging-before-etching flip chip 3D system-in-package metal circuit board structure of claim 3, wherein step 5 to step 17 are repeated for times between step 8 and step 18.

5. A packaging-before-etching flip chip 3D system-in-package metal circuit board structure, comprising: a metal substrate frame (1); a die pad (2) and a lead (3) provided in the metal substrate frame (1); a conductive pillar (4) provided on a front surface of the lead (3); a chip (5) is flipped on a front surface of the die pad (2) and the lead (3) by underfills; a molding material or epoxy resin (7) with which a periphery region of the die pad (2), the lead (3), the conductive pillar (4) and the chip (5) is encapsulated, with the molding material or epoxy resin (7) being flushed with the top of the conductive pillar (4); and an anti-oxidizing layer (6) provided on a surface of the metal substrate frame (1), the die pad (2), the lead (3) and the conductive pillar (4) exposed from the molding material or epoxy resin (7).

6. The packaging-before-etching flip chip 3D system-in-package metal circuit board structure of claim 5, wherein multi-turn leads (3) are provided.

7. The packaging-before-etching flip chip 3D system-in-package metal circuit board structure of claim 5, wherein a passive device (10) is connected across the leads (3).

8. The packaging-before-etching flip chip 3D system-in-package metal circuit board structure of claim 5, wherein an electrostatic discharge coil (11) is provided between the die pad (2) and the lead (3).

9. The packaging-before-etching flip chip 3D system-in-package metal circuit board structure of claim 7, wherein an electrostatic discharge coil (11) is provided between the die pad (2) and the lead (3).

10. The packaging-before-etching flip chip 3D system-in-package metal circuit board structure of claim 5, wherein a plurality of chips (5) are flipped on a front surface of the die pads (2) and the leads (3).

11-13. (canceled)

14. The first-packaged and later-etched normal chip dimension system-in-package metal circuit board structure of claim 5, wherein a second chip (12) is mounted normally on the back surface of the chip (5), and the second chip (12) is connected to the lead (3) via a metal wire (15).

15-16. (canceled)

17. The packaging-before-etching flip chip 3D system-in-package metal circuit board structure of claim 9, wherein a second chip (12) is normally mounted on the back surface of the chip (5), and the second chip (12) is connected to the lead (3) via a metal wire (15).

18-21. (canceled)

22. The packaging-before-etching flip chip 3D system-in-package metal circuit board structure of claim 5, wherein a second conductive pillar (13) is provided on the front surface of the lead (3), a second chip (12) is flipped on the second conductive pillar (13) by a conductive material (14), the second chip (12) is located above the chip (5), and the second conductive pillar (13) and the second chip (12) are located inside the molding material (7).

23-24. (canceled)

25. The packaging-before-etching flip chip 3D system-in-package metal circuit board structure of claim 9, wherein a second conductive pillar (13) is provided on the front surface of the lead (3), a second chip (12) is flipped on the second conductive pillar (13) by a conductive material (14), the second chip (12) is located above the chip (5), and the second conductive pillar (13) and the second chip (12) are located inside the molding material (7).

26-38. (canceled)

39. The packaging-before-etching flip chip 3D system-in-package metal circuit board structure of claim 22, wherein the second chip (12) is replaced by a passive device (10).

40. A packaging-before-etching flip chip 3D system-in-package metal circuit board structure manufactured by the method according to claim 1 comprising: a metal substrate frame (1); a lead (3) provided in the metal substrate frame (1); a conductive pillar (4) provided on a front surface of the lead (3); a chip (5) is flipped between the leads (3) by underfills; a molding material (7) with which a periphery region of the lead (3), the conductive pillar (4) and the chip (5) is encapsulated, with the molding material (7) being flushed with the top of the conductive pillar (4); and an anti-oxidizing layer (6) provided on a surface of the metal substrate frame (1), the lead (3) and the conductive pillar (4) exposed from the molding material (7l).

41. (canceled)

42. A packaging-before-etching flip chip 3D system-in-package metal circuit board structure of claim 5, wherein, the 3D system-in-package metal circuit board structure serves as a converter after being cut.

43. A packaging-before-etching flip chip 3D system-in-package metal circuit board structure of claim 40, wherein, the 3D system-in-package metal circuit board structure serves as a converter after being cut.
